(19) United States
(12) Patent Application Publication
(10) Pub. No.: US 2022/0123013 A1
(43) Pub. Date: Apr. 21, 2022

(54) THREE-DIMENSIONAL SEMICONDUCTOR DEVICE AND METHOD OF FABRICATION THEREOF

(71) Applicant: Yangtze Memory Technologies Co., Ltd., Wuhan (CN)

(72) Inventors: Tingting GAO, Wuhan (CN); Lei XUE, Wuhan (CN); Xiaoxin LIU, Wuhan (CN); Wanbo GENG, Wuhan (CN)

(73) Assignee: Yangtze Memory Technologies Co., Ltd., Wuhan (CN)

(21) Appl. No.: 17/116,638

(22) Filed: Dec. 9, 2020

Related U.S. Application Data
(63) Continuation of application No. PCT/CN2020/121812, filed on Oct. 19, 2020.

(51) Int. Cl. H01L 27/11582; H01L 21/02; H01L 21/311; H01L 27/11565; H01L 21/28; H01L 29/423

(52) U.S. Cl. CPC H01L 27/11582; H01L 21/02236; H01L 21/31133; H01L 29/4234; H01L 27/11565; H01L 29/40117; H01L 21/31144

(57) ABSTRACT

Aspects of the disclosure provide a semiconductor device and a method for manufacturing the semiconductor device. A channel hole is formed through a stack over a substrate of the semiconductor device. A sidewall of the channel hole extends along a vertical direction perpendicular to the substrate. A gate dielectric structure, a channel layer, and a dielectric structure that extend along the vertical direction are formed in the channel hole. The gate dielectric structure can be formed along the sidewall of the channel hole, and the dielectric structure can be formed over the channel layer. The channel layer can be separated into channel layer sections to form a channel structure that includes the gate dielectric structure and the channel layer sections for respective strings of transistors.

### RELATED APPLICATION

This application is a bypass continuation of International Application No. PCT/CN2020/121812, filed on Oct. 19, 2020. The entire disclosure of the prior application is hereby incorporated by reference in its entirety.

### TECHNICAL FIELD

The present application describes embodiments generally related to semiconductor memory devices.

### BACKGROUND

As critical dimensions of devices in integrated circuits shrink to the limits of memory cell technologies, techniques are developed to achieve greater storage capacity. Compared to a planar transistor structure, a vertical structure of a 3D semiconductor memory device can include more complex manufacturing processes. As the 3D semiconductor memory device migrates to configurations with more memory cell layers to achieve higher densities at a lower cost per bit, it becomes an increasing challenge to improve structures and methods for manufacturing the same.

### SUMMARY

Aspects of the disclosure provide a method for forming a semiconductor device. The method includes forming a channel hole through a stack over a substrate of the semiconductor device where a sidewall of the channel hole extends along a vertical direction perpendicular to the substrate. The method includes forming a gate dielectric structure, a channel layer, and a dielectric structure that extend along the vertical direction and in the channel hole. The gate dielectric structure is formed along the sidewall of the channel hole and the dielectric structure is formed over the channel layer. The method includes separating the channel layer into channel layer sections to form a channel structure that includes the gate dielectric structure and the channel layer sections for respective strings of transistors. In an example, separating the channel layer into channel layer sections includes forming a hole inside the dielectric structure using a first etching process with an etching mask. The method includes removing portions of the dielectric structure adjacent to first portions of the channel layer using a second etching process where second portions of the channel layer being separated from the hole by the dielectric structure.

In an embodiment, forming the gate dielectric structure includes forming a barrier layer, a charge trapping layer, and a tunneling layer sequentially along the vertical direction where the barrier layer is formed along the sidewall of the channel hole and in contact with the stack. Forming the channel layer includes forming the channel layer over an inner surface of the tunneling layer. Forming the dielectric structure includes forming the dielectric structure over an inner surface of the channel layer. The stack includes alternating sacrificial layers and insulating layers. The method further includes replacing the sacrificial layers with gate line layers.

In an embodiment, the separating the channel layer further comprises removing the first portions of the channel layer by an etching process to separate the channel layer into the channel layer sections and depositing a dielectric material. The hole includes voids corresponding to the removed first portions of the channel layer. The dielectric material deposited in the voids is disposed between adjacent ones of the channel layer sections.

In an example, the removing the first portions of the channel layer further includes removing first portions of the tunneling layer that are adjacent to the first portions of the channel layer by the etching process to separate the tunneling layer into the tunneling layer sections. The dielectric material can be deposited between adjacent ones of the tunneling layer sections.

In an example, the removing the first portions of the channel layer further includes (i) removing first portions of the tunneling layer that are adjacent to the first portions of the channel layer by the etching process to separate the tunneling layer into the tunneling layer sections and (ii) removing first portions of the charge trapping layer that are adjacent to the first portions of the tunneling layer by the etching process to separate the charge trapping layer into the charge trapping layer sections. The dielectric material can be deposited between adjacent ones of the tunneling layer sections and adjacent ones of the charge trapping layer sections.

In an embodiment, the separating the channel layer further comprises oxidizing the first portions of the channel layer into an oxidized material to separate the channel layer into the channel layer sections and depositing a dielectric material into the hole. The oxidized material is disposed between adjacent ones of the channel layer sections.

In an embodiment, the gate dielectric structure includes a barrier layer, a charge trapping layer, and a tunneling layer that are sequentially formed along the vertical direction. The barrier layer being formed along the sidewall of the channel hole. The method further includes oxidizing portions of the tunneling layer to separate the tunneling layer into tunneling layer sections and/or oxidizing portions of the charge trapping layer to separate the charge trapping layer into charge trapping layer sections, the tunneling layer sections and the charge trapping layer sections corresponding to the channel layer sections.

In an embodiment, a cross-section of the channel hole that is perpendicular to the vertical direction has a plurality of axes of symmetry. A first distance is a smallest distance among distances between a center point at which the plurality of axes of symmetry intersects and respective points on the sidewall of the cross-section of the channel hole. A second distance is a largest distance among the distances. The first distance is less than the second distance. In an example, the cross-section of the channel hole has one of an oval profile, a trefoil profile, a quatrefoil profile, and a star profile. In an example, a number of the plurality of axes of symmetry is larger than 1. In an example, a ratio of the second distance over the first distance is in a range of 1.5 to 2.

In an embodiment, the channel layer sections include four channel layer sections where each of the four channel layer sections corresponds to a different one of the strings of transistors. The four channel layer sections are arranged at ends of perpendicular axes of symmetry in a cross-section of the channel hole that is perpendicular to the vertical direction.

Aspects of the disclosure provide a semiconductor device. The semiconductor device includes a channel hole in a stack over a substrate of the semiconductor device. A sidewall of the channel hole extending along a vertical direction that is perpendicular to the substrate. The semiconductor device includes a channel structure that is disposed in the channel hole where the channel structure extends along the vertical direction. A cross-section of the channel structure that is perpendicular to the vertical direction includes physically separated channel layer sections for respective strings of transistors and a first dielectric material disposed between adjacent ones of the channel layer sections. The semiconductor device includes gate structures in the stack that surround the channel structure.

In an embodiment, the channel structure further comprises a gate dielectric structure. The gate dielectric structure includes a barrier layer that is formed along the sidewall of the channel hole and extends in the vertical direction where the barrier layer is in contact with the gate structures. The gate dielectric structure includes a charge trapping layer that is formed over an inner surface of the barrier layer and a tunneling layer that is formed over an inner surface of the charge trapping layer. The channel layer sections are arranged over an inner surface of the tunneling layer and the first dielectric material is in contact with the tunneling layer.

In an embodiment, the channel structure further includes a second dielectric material that is formed over inner surfaces of the respective channel layer sections where the second dielectric material is different from the first dielectric material.

In an embodiment, cross-sections of the barrier layer, the charge trapping layer, and the tunneling layer perpendicular to the vertical direction have a closed-loop configuration.

In an example, the cross-section of the tunneling layer is discontinues. The tunneling layer includes a plurality of tunneling layer sections that correspond to the respective channel layer sections. The plurality of tunneling layer sections is spaced apart from each other by the first dielectric material.

In an example, a cross-section of the charge trapping layer that is perpendicular to the vertical direction is discontinuous. The charge trapping layer includes a plurality of charge trapping layer sections that correspond to the respective tunneling layer sections. The plurality of charge trapping layer sections is spaced apart from each other by the first dielectric material.

In an embodiment, a cross-section of the channel hole that is perpendicular to the vertical direction has a plurality of axes of symmetry. A first distance is a smallest distance among distances between a center point at which the plurality of axes of symmetry intersects and respective points on the sidewall of the cross-section of the channel hole. A second distance is a largest distance among the distances. The first distance is less than the second distance. In an example, the cross-section of the channel hole has one of an oval profile, a trefoil profile, a quatrefoil profile, and a star profile. In an example, a number of the plurality of axes of symmetry is larger than 1. A ratio of the second distance over the first distance is in a range of 1.5 to 2.

In an embodiment, the channel layer sections include four channel layer sections where each of the four channel layer sections corresponds to a different one of the strings of transistors. The four channel layer sections are arranged at ends of perpendicular axes of symmetry in a cross-section of the channel hole that is perpendicular to the vertical direction.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a cross-sectional view of an exemplary 3D semiconductor device according to an embodiment of the disclosure.

FIG. 2A is a top-down view showing a cross-section of an exemplary channel structure that is perpendicular to a vertical axis according to an embodiment of the disclosure.

FIG. 2B is a cross-sectional view of a channel structure that is parallel to the vertical axis according to an embodiment of the disclosure.

FIG. 2C is a top-down view showing a cross-section of an exemplary channel structure that is perpendicular to the vertical axis according to an embodiment of the disclosure.

FIG. 2D is a top-down view showing a cross-section of an exemplary channel structure that is perpendicular to the vertical axis according to an embodiment of the disclosure.

FIG. 2E is a top-down view showing a cross-section of an exemplary channel structure that is perpendicular to the vertical axis according to an embodiment of the disclosure.

FIG. 2F is a top-down view showing a cross-section of an exemplary channel structure that is perpendicular to the vertical axis according to an embodiment of the disclosure.

FIG. 2G is a top-down view showing a cross-section of an exemplary channel structure that is perpendicular to the vertical axis according to an embodiment of the disclosure.

FIG. 2H is a top-down view showing a cross-section of an exemplary channel structure that is perpendicular to the vertical axis according to an embodiment of the disclosure.

FIGS. 3-6, 7A-7C, 8A-8C, and 9A-9C show top-down views of cross-sections corresponding to various steps of manufacturing a 3D semiconductor device according to aspects of the disclosure.

FIG. 10 is a flow chart of a process for manufacturing a 3D semiconductor device according to an embodiment of the disclosure.

FIGS. 11-14, 15A-15D, 16A-16D, and 17A-17D show top-down views of cross-sections corresponding to various steps of manufacturing a 3D semiconductor device according to aspects of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A 3D semiconductor device (e.g., a 3D-NAND memory device) can include a plurality of channel structures formed in a stack of gate line layers and insulating layers over a substrate of the 3D semiconductor device. ne of the plurality of channel structures, referred to as the channel structure, can be formed in a channel hole in the stack. According to aspects of the disclosure, the channel structure can include a channel layer that has an open-loop (or discontinuous) configuration in which the open-loop channel layer is separated into multiple channel layer sections. The channel structure including the open-loop channel layer can be referred to as the open-loop channel structure or the channel structure having an open-loop configuration. Thus, a single transistor (e.g., a memory cell or MC) formed based on a channel layer (or a continuous channel layer) having a closed-loop configuration can be split into multiple transistors (e.g., multiple MCs) formed based on the multiple channel layer sections. Accordingly, a single transistor string (e.g., a MC string) can be split into multiple transistor strings (e.g., multiple MC strings) formed based on the channel structure to increase a transistor density (or a storage density, a bit density) of the 3D semiconductor device.

In order to manufacture the open-loop channel structure, a pre-channel structure can be formed inside the channel hole along a vertical direction that is perpendicular to a surface of the substrate of the 3D semiconductor device. Cross-sections of the channel structure and the channel hole perpendicular to the vertical direction can be anisotropic. The cross-section of the channel hole can include different axes of symmetry. The cross-section of the channel hole includes at least one long axis and at least one short axis. In an example, the at least one long axis and the at least one short axis correspond to the different axes of symmetry for the channel hole. The pre-channel structure can include a gate dielectric structure, the closed-loop channel layer, and a dielectric structure (also referred to as an isolation structure) that can be sequentially formed in the channel hole and extend along the vertical direction. A hole can be formed in the dielectric structure, for example, by an etching process with an etching mask, to expose first portions of the closed-loop channel layer while remaining portions (or second portions) of the closed-loop channel layer are not exposed and are separated from the hole by the isolation structure. In an example, the first portions of the closed-loop channel layer are adjacent to the at least one short axis.

The closed-loop channel layer can be subsequently divided into the multiple channel layer sections based on the exposed first portions of the closed-loop channel layer, and thus becoming the open-loop channel layer. In an example, an etching process is applied to remove third portions of the closed-loop channel layer. The third portions can include the exposed first portions. In an example, an oxidation process (e.g., a polysilicon oxidation process) is applied to oxidize the third portions of the closed-loop channel layer into an oxidized material (e.g., silicon oxide), and thus dividing the closed-loop channel layer into the multiple channel layer sections. Accordingly, the third portions of the closed-loop channel layer can be removed or oxidized into the oxide material, and remaining portions of the closed-loop channel layer can become the multiple channel layer sections. In an example, the third portions of the closed-loop channel layer are adjacent to the at least one short axis, and the multiple channel layer sections are adjacent to, or aligned with, the at least one long axis.

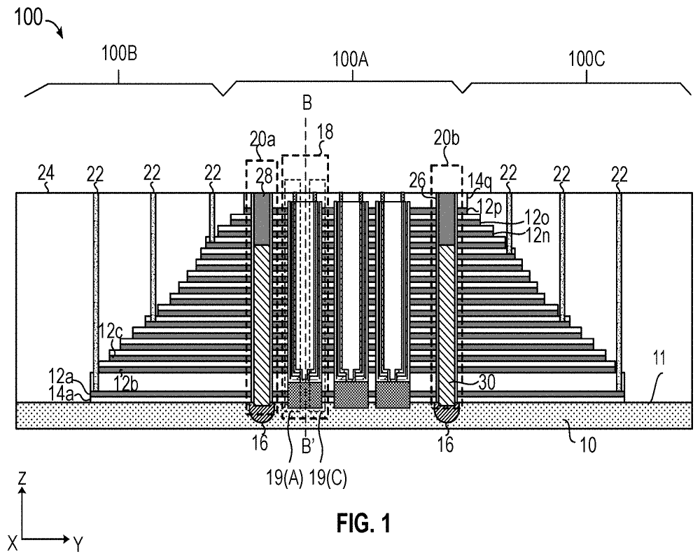

FIG. 1 is a cross-sectional view of an exemplary 3D semiconductor device (e.g., a 3D-NAND memory device) 100. The 3D semiconductor device 100 can have a substrate 10 including a working surface 11. A plurality of gate line layers 12 and a plurality of insulating layers 14 can be stacked alternatingly over the substrate 10. Any number of gate line layers and any number of insulating layers can be included in the 3D semiconductor device 100, for example, based on device and/or performance requirements. In an example, 16 gate line layers 12a-12p and 17 insulating layers 14a-14q are shown in FIG. 1.

Referring to FIG. 1, the plurality of gate line layers 12 can include bottom select gate (BSG) layer(s), a plurality of word line layers, and top select gate (TSG) layer(s) that are disposed sequentially over the substrate 10. The BSG layer(s) can include a lowermost gate line layer 12a. In some embodiments, one or more of the gate line layers over the BSG layer 12a, such as gate line layer 12b-12c, can be dummy gate line layers (or dummy BSG layers). The TSG layer(s) can include an uppermost gate line layer 12p. In some embodiments, one or more of the gate line layers under the TSG layer 12p, such as gate line layers 12n-12o, can be dummy gate line layers (or dummy TSG layers). Bottom select transistor(s) (BST(s)) can be formed based at least on the BSG layer 12a and can control data transmission between array common source (ACS) regions 16 and a plurality of MCs formed based on the plurality of word line layers (e.g., 12d-12m). Top select transistor(s) (TST(s)) can be formed based at least on the TSG layer 12p and can control data transmission between bit lines (not shown) and the plurality of MCs formed based on the plurality of word line layers. In an example, the BST(s) can include a BST and dummy MCs that are formed based on the BSG layer 12a and the dummy BSG layers (e.g., 12b-12c), respectively. The TST(s) can include a TST and dummy MCs that are formed based on the TSG layer 12p and the dummy TSG layers (e.g., 12n-12o), respectively. The plurality of MCs can be formed based on the plurality of word line layers 12d-12m.

The plurality of gate line layers 12 can be formed based on a plurality of sacrificial gate line layers (also referred to as sacrificial layers, such as silicon nitride layers). The plurality of sacrificial gate line layers can be removed and replaced with the plurality of gate line layers 12, respectively. Each of the plurality of gate line layers 12 can include a high dielectric constant (high K) sublayer, glue sublayer(s), and metal sublayer(s). Each of the plurality of gate line layers 12 can include the high K sublayer and the metal sublayer(s). The high K layer can include aluminum oxide (Al₂O₃), hafnium oxide (HfO₂), tantalum oxide (Ta₂O₅), and/or another high K material. The metal layer(s) can include tungsten (W), cobalt (Co), and/or another metal material. The plurality of gate lines layers 12 can have any suitable thicknesses, such as from 10 nm to 100 nm, according to requirements of product specification, device operation, manufacturing capabilities, and/or the like. The plurality of gate lines layers 12 can have identical or different thicknesses. The plurality of gate lines layers 12 can have identical or different sublayers.

The plurality of insulating layers 14 can be positioned on the substrate 10 and arranged with the plurality of gate line layers 12 alternatingly. The plurality of gate line layers 12 can be spaced part from one another by the plurality of insulating layers 14. In addition, the plurality of gate line layers 12 can be separated from the substrate 10 by a lowermost insulating layer 14a in the plurality of insulating layers 14. The plurality insulation layers 14 can have identical or different thicknesses. The plurality insulation layers 14 can have identical or different material(s). In an example, each of the plurality of insulating layers 14 is made of SiO₂ with a thickness from 5 nm to 50 nm.

The 3D semiconductor device 100 can include staircase region(s) (e.g., staircase regions 100B-100C) and array region(s) (e.g., an array region 100A) that are formed in a stack of the plurality of gate line layers 12 and the plurality of insulating layers 14.

The array region 100A can include a plurality of channel structures 18. The plurality of channel structures 18 can be coupled to the plurality of gate line layers 12 to form respective MC strings. The MC strings can be NAND MC strings that are vertically stacked along a vertical direction (also referred to as a height direction or a Z direction). The vertical direction can be perpendicular to the working surface 11 of the substrate 10. Each of the MC strings can include the BST(s), the plurality of MCs, and the TST(s) that are disposed sequentially and in series over the substrate 10 along the vertical direction. The BST(s), the plurality of MCs, and the TST(s) can be formed based on the BSG layer(s), the plurality of word line layers, and the TSG layer(s), respectively, as described above.

The channel structure 18 can be formed over the substrate 10 along the vertical direction. The channel structure 18 can extend through the plurality of gate line layers 12 and the plurality of insulating layers 14, and can further extend into the substrate 10. Any suitable number of channel structures 18 can be included in the 3D semiconductor device 100.

According to aspects of the disclosure, the channel structure 18 can include an open-loop channel layer and a gate dielectric structure (e.g., including a tunneling layer, a charge trapping layer, and a barrier layer) arranged around a vertical axis B-B′ that is parallel to the vertical direction. The open-loop channel layer (or the discontinuous channel layer) can include multiple channel layer sections that are separated, and thus multiple MC strings (e.g., MC strings 19(A) and 19(C)) can be formed based on the multiple channel layer sections in the channel structure 18.

The 3D semiconductor device 100 can include a plurality of slit structures (or gate line slit structures), such as the slit structures 20a-20b. The 3D semiconductor device 100 can include any suitable number of slit structures and the slit structures can be located at any suitable locations. In some embodiments, a gate-last fabrication technology is used to form the 3D semiconductor device 100, thus the slit structures 20a-20b are formed to assist in removing the sacrificial gate line layers, and the subsequent formation of the plurality of gate line layers 12. The slit structures 20a-20b can be made of conductive materials and positioned on the ACS regions 16 to serve as contacts where the ACS regions 16 can be formed in the substrate 10 to serve as common sources. The slit structures 20a-20b can also be made of dielectric materials to serve as separation structures. In an example, the slit structures 20a-20b are positioned at two opposing boundaries of the array region 100A and connected to the ACS regions 16.

The slit structures 20a-20b can extend through the plurality of gate line layers 12 and the plurality of insulating layers 14, and further extend along a first direction (also referred to as a length direction, or an X direction) that is perpendicular to the vertical direction. Each of the slit structures 20a-20b can have a dielectric spacer 26, a conductive layer 30, and a contact 28. The dielectric spacer 26 can be formed along sidewalls of the respective slit structure 20a-20b and in direct contact with the plurality of gate line layers 12 and the plurality of insulating layers 14. The conductive layer 30 can be formed along the dielectric spacer 26 and over the respective ACS region 16. The contact 28 can be formed along the dielectric spacer 26 and over the conductive layer 30. In an example, the dielectric spacer 26 includes silicon dioxide (SiO₂), the conductive layer 30 includes polysilicon, and the contact 28 includes W.

In the 3D semiconductor device 100, the plurality of gate line layers 12 and the plurality of insulating layers 14 can extend into the staircase region 100B-100C with a stair-cased profile or step-cased profile. Thus, the staircase regions 100B-100C can include stairs formed in the plurality of gate line layers 12 and gate line contacts 22 formed on the stairs to connect to the plurality of gate line layers 12. The staircase regions 100B-100C can be positioned at two sides of the array region 100A.

The 3D semiconductor device 100 can have a plurality of gate line contact structures 22. The gate line contact structures 22 can be formed in a dielectric layer 24 and positioned on the respective gate line layers 12. For simplicity and clarity, three gate line contact structures 22 are illustrated in each of the staircase regions 100B and 100C. The gate line contact structures 22 can further be coupled to gate voltages. The gate voltages can be applied to gate structures of the BST(s), the plurality of MCs, and the TST(s) through the plurality of gate line layers 12 to operate the BST(s), the plurality of MCs, and the TST(s), respectively.

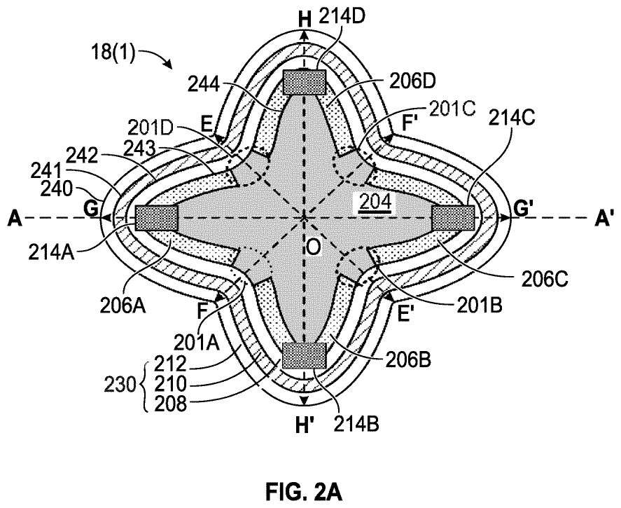

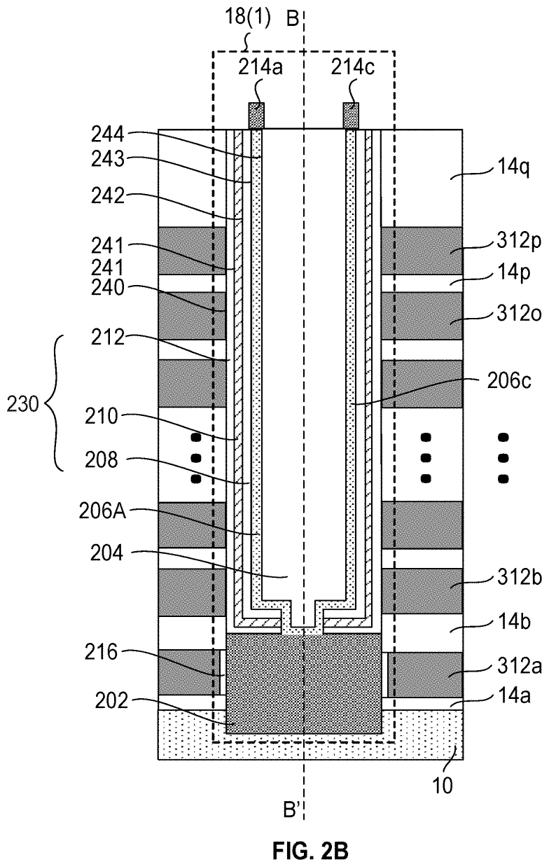

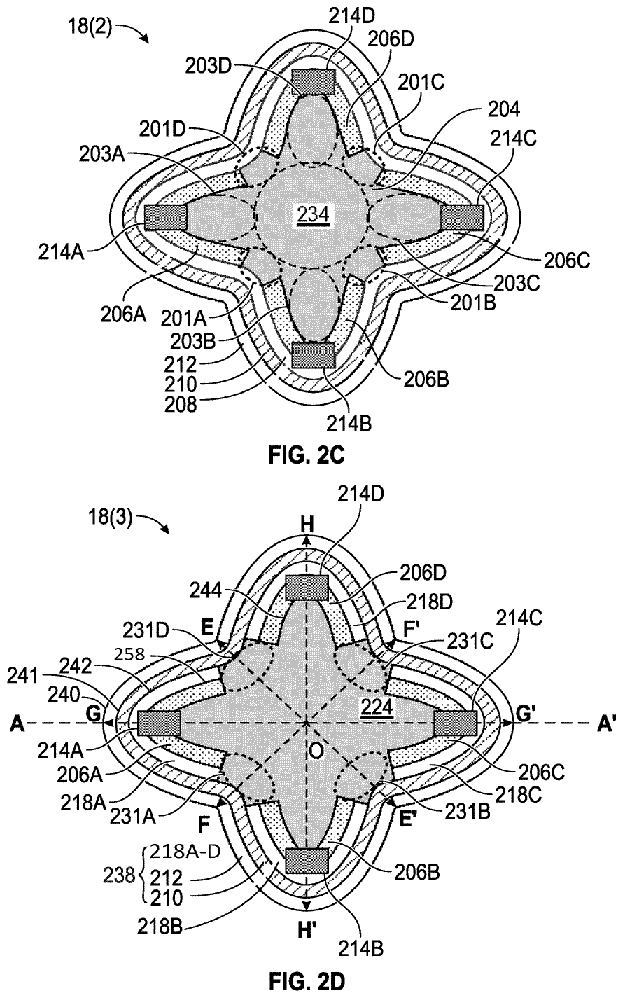

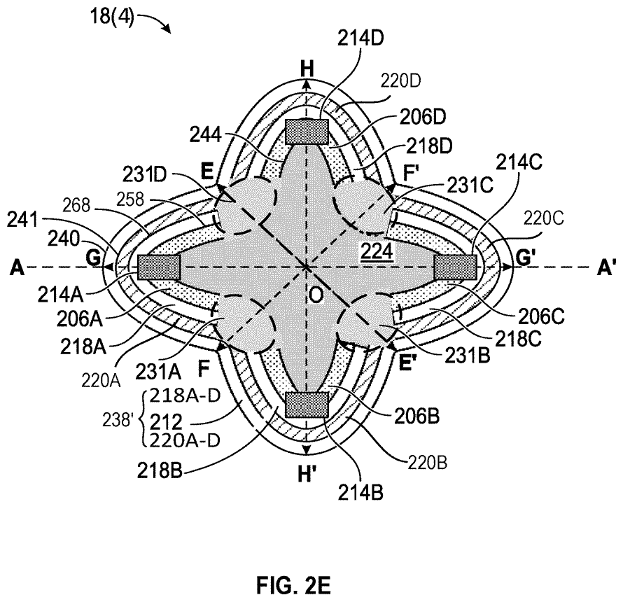

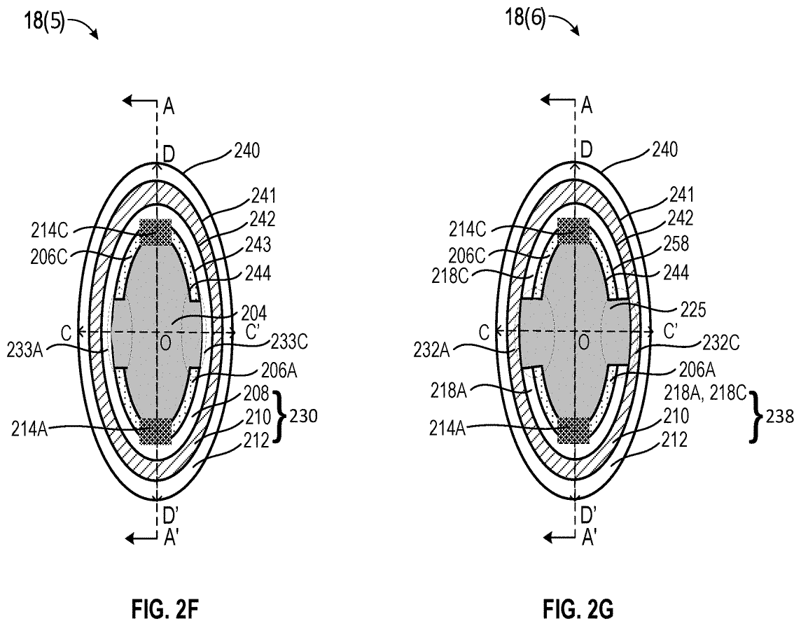

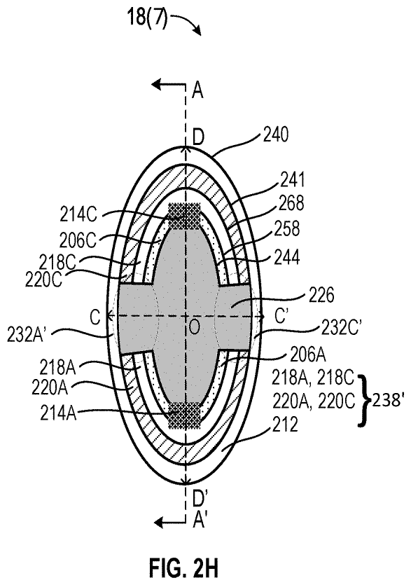

FIG. 2A is a top-down view showing a cross-section of an example (referred to as a channel structure 18(1)) of the channel structure 18 that is perpendicular to the vertical axis B-B′ according to an embodiment of the disclosure. FIG. 2B is a cross-sectional view of the channel structure 18(1) obtained from a plane including line A-A′ in FIG. 2A and the vertical axis B-B′. The line A-A′ and the vertical axis B-B′ intersect at a point 0. Referring to FIGS. 2A-2B, the channel structure 18(1) can be formed along the vertical direction perpendicular to the working surface 11 of the substrate 10, and electrically coupled with the substrate 10 via a bottom channel contact 202 of the channel structure 18(1). The channel structure 18(1) can be formed along a sidewall 240 of a channel hole (not shown) in the stack of the alternating plurality of gate line layers 12 and the plurality of insulation layers 14. A cross-section of the sidewall 240 perpendicular to the vertical axis B-B′ and the cross-section of the channel structure 18(1) can include at least one short axis (e.g., axes E-E′ and F-F′) and at least one long axis (e.g., axes H-H′ and G-G′) that are perpendicular to the vertical axis B-B′. The at least one short axis (e.g., the axes E-E′ and F-F′) and the at least one long axis (e.g., the axes H-H′ and G-G′) can intersect at the point 0. The axes E-E′, F-F′, H-H′, and G-G′ intersect with the sidewall 240 at points E, E′, F, F′, H, H′, G, and G′, respectively.

Referring to FIG. 2A, the cross-sections of the sidewall 240 and the channel structure 18(1) can be anisotropic. First distances OE, OE′, OF, and OF′ can be smallest among distances between the point O and respective points on the cross-section of the sidewall 240. Second distances OH, OH′, OG, and OG′ can be largest among the distances between the point O and respective points on the cross-section of the sidewall 240. The first distances OE, OE′, OF, and OF′ are shorter than the second distances OH, OH′, OG, and OG′. Similarly, distances EE′ and FF′ along the respective short axes E-E′ and F-F′ are shorter than distances GG′ and HH′ along the respective long axes G-G′ and H-H′. A ratio of one (e.g., OH) of the second distances over one (e.g., OE) of the first distances can be larger than 1, such as in a range of 1.5 to 2. In an example, the cross-sections of the sidewall 240 and the channel structure 18(1) are symmetric with respect to the point O. In an example, each of the cross-sections of the sidewall 240 and the channel structure 18(1) is mirror symmetric and has a plurality of axes of symmetry. The plurality of axes of symmetry for the sidewall 240, such as the axes E-E′, F-F′, H-H′ and G-G′, can be identical to that of the channel structure 18(1). Thus, the first distances OE, OE′, OF, and OF′ are identical, and the second distances OH, OH′, OG, and OG′ are identical.

Referring to FIGS. 2A-2B, the channel structure 18(1) can have a gate dielectric structure 230. The gate dielectric structure 230 can include a barrier layer 212, a charge trapping layer 210, and a tunneling layer 208. In an example, such as shown in FIG. 2A, cross-sections of the barrier layer 212, the charge trapping layer 210, and the tunneling layer 208 perpendicular to the vertical direction have a closed-loop configuration.

The barrier layer 212 can be formed along the vertical direction. The barrier layer 212 can be conformably formed along the sidewall 240 of the channel hole and over the bottom channel contact 202. The barrier layer 212 can be in direct contact with a plurality of gate structures 312 (e.g., the gate structures 312a-312p in FIG. 2B) and the plurality of insulating layers 14. The plurality of gate structures 312 can be connected and electrically coupled to the plurality of gate line layers 12, respectively. The charge trapping layer 210 can be conformably formed over an inner surface 241 of the barrier layer 212, and the tunneling layer 208 can be conformably formed over an inner surface 242 of the charge trapping layer 210.

The channel structure 18(1) can further include a channel layer (or an open-loop channel layer) that has channel layer sections 206A-206D conformably formed over an inner surface 243 of the tunneling layer 208. The channel layer can have an open-loop configuration where the channel layer includes the channel layer sections 206A-206D that are separated, for example, by dielectric sections 201A-201D. FIG. 2B shows the channel layer sections 206A and 206C. A bottom portion of the channel layer can be positioned over and in direct contact with the bottom channel contact 202.

In some embodiments, the barrier layer 212, the charge trapping layer 210, the tunneling layer 208, and the channel layer sections 206A-206D can be arranged concentrically around the vertical axis B-B′ in the vertical direction. In addition, the channel layer sections 206A and 206C can be separately arranged at opposing ends of the long axis G-G′, and the channel layer sections 206B and 206D can be separately arranged at opposing ends of the long axis H-H′.

Referring to FIGS. 2A-2B, the channel structure 18(1) can include a channel dielectric structure (also referred to as a channel isolation structure, a dielectric structure, or an isolation structure) 204 disposed along, for example, inner surfaces 244 of the channel layer sections 206A-206D to fill the channel structure 18(1). In an example, the channel dielectric structure 204 fills the channel structure 18(1) completely as shown in FIG. 2A. Alternatively, the channel dielectric structure 204 can fill the channel structure 18(1) partially. The channel dielectric structure 204 can include dielectric sections 201A-201D between adjacent ones of the channel layer sections 206A-206D so that the channel layer sections 206A-206D are spaced apart from each other. The dielectric sections 201A-201D can be arranged along the inner surface 243 of the tunneling layer 208. In an example shown in FIG. 2A, the dielectric sections 201A-201D can be arranged adjacent to the at least one short axis (e.g., the axes E-E′ and F-F′). For example, the dielectric section 201A is disposed between the channel layer sections 206A-206B and is adjacent to the axis F-F′, the dielectric section 201B is disposed between the channel layer sections 206B-206C and is adjacent to the axis E-E′, the dielectric section 201C is disposed between the channel layer sections 206C-206D and is adjacent to the axis F-F′, and the dielectric section 201D is disposed between the channel layer sections 206D and 206A and is adjacent to the axis E-E′.

The channel structure 18(1) can include top channel contacts 214A-214D that are formed, for example, over and in direct contact with the respective channel layer sections 206A-206D. For example, the top channel contact 214A can be formed over the channel layer section 206A, the top channel contact 214B can be formed over the channel layer section 206B, the top channel contact 214C can be formed over the channel layer section 206C, and the top channel contact 214D can be formed over the channel layer section 206D. The top channel contacts 214A-214D (e.g., the top channel contacts 214A and 214C shown in FIG. 2B) can be positioned above the gate structure 312p that is connected to the TSG layer 12p to prevent electrical interference between the top channel contacts 214A-214D and the gate structure 312p and/or the TSG layer 12p.

Referring to FIG. 2B, a gate dielectric layer 216 can be formed between the bottom channel contact 202 and the gate structure 312a that is connected to the BSG layer 12a. The gate dielectric layer 216 can be positioned between the insulating layer 14b and 14a and surround the bottom channel contact 202.

The barrier layer 212 can include one or more dielectric materials, such as SiO₂, Al₂O₃, and/or the like. The barrier layer 212 can include one or more sublayers. The charge trapping layer 210 can include one or more dielectric materials, such as SiN, SiON, and/or the like. The charge trapping layer 210 can include one or more sublayers. In an example, the charge trapping layer 210 includes a multi-sublayer configuration, such as a SiN/SiON/SiN configuration. The tunneling layer 208 can include one or more dielectric materials. The tunneling layer 208 can include one or more sublayers, such as a multi-sublayer (e.g., SiO/SiON/SiO) configuration. The channel layer can include conductive material(s), such as polysilicon (e.g., formed using a furnace low pressure chemical vapor deposition (CVD) process). The channel dielectric structure 204 can include dielectric material(s), such as SiO₂. The top channel contacts 214A-214D and the bottom channel contact 202 can include conductive material(s), such as polysilicon.

The cross-section of the sidewall 240 (or the cross-section of the channel hole) and the cross-section of the channel structure 18(1) can have various profiles, such as any suitable anisotropic profile. The anisotropic profile can be one of an oval profile, a trefoil profile, a quatrefoil profile, a star profile, and the like. The anisotropic profile can be symmetric or asymmetric. As described above, the cross-section of the sidewall 240 (or the cross-section of the channel hole) can be mirror symmetric and include the plurality of axes of symmetry (e.g., E-E′, F-F′, G-G′, and H-H′). A number of the plurality of axes of symmetry can be larger than 1, such as 2, 3, 4, and 5 for the oval profile, the trefoil profile, the quatrefoil profile, and the star profile, respectively.

Referring to FIG. 2A, the cross-section of the sidewall 240 (or the cross-section of the channel hole) and the cross-section of the channel structure 18(1) have a quatrefoil profile. The four channel layer sections 206A-206D are arranged at opposing ends of the perpendicular long axes G-G′ and H-H′ in the cross-section of the sidewall 240. Accordingly, four MC strings can be formed based on the channel structure 18(1) and the gate structures 312. The four MC strings can be formed based on the respective channel layer sections 206A-206D, the gate dielectric structure 230, and the gate structures 312. For example, a first MC string is formed based on the channel layer section 206A, a second MC string is formed based on the channel layer section 206B, a third MC string is formed based on the channel layer section 206C, and a fourth MC string is formed based on the channel layer section 206D. Thus, the bit density of the 3D semiconductor device 100 can be quadrupled as compared to a device having a closed-loop channel layer and a gate dielectric structure that is identical to the gate dielectric structure 230.

Referring to FIG. 2A, the channel structure 18(1) shows a four-phase split cell configuration (e.g., four-phase split MC configuration) where four separate cells (e.g., four separate MCs) can be formed based on the channel structure 18(1) (e.g., the channel layer sections 206A-206D). The channel layer including the separated channel layer sections 206A-206D has a split channel configuration.

The channel dielectric structure 204 can include any suitable dielectric material(s). Distribution of the dielectric material(s) in the channel dielectric structure 204 can be uniform (e.g., as shown in FIG. 2A) or non-uniform (e.g., as shown below in FIG. 2C). FIG. 2C shows an example of the channel structure 18 that is referred to as the channel structure 18(2). The channel structure 18(2) in FIG. 2C is identical to the channel structure 18(1) in FIG. 2A except the channel dielectric structure 204. Referring to FIG. 2C, the channel dielectric structure 204 includes different dielectric materials, such as at least a first dielectric material and a second dielectric material that is different from the first dielectric material, and the different dielectric materials (e.g., the first dielectric material and the second dielectric material) are distributed at different locations within the channel dielectric structure 204 in FIG. 2C.

Referring to FIG. 2C, the channel dielectric structure 204 can include dielectric sections 203A-203D, the dielectric sections 201A-201D, and a central dielectric section 234. The dielectric sections 201A-201D can include the first dielectric material. The dielectric sections 203A-203D that are formed over the inner surfaces 244 of the respective channel layer sections 206A-206D can include the second dielectric material. The central dielectric section 234 can include a third dielectric material that is identical to the first dielectric material or the second dielectric material. Alternatively, the third dielectric material can be different from the first and second dielectric materials. In an example, the first dielectric material, the second dielectric material, and the third dielectric material are oxide materials (e.g., silicon oxide) having identical or different densities.

Shapes of the dielectric sections 201A-201D and 203A-203D and the central dielectric section 234 shown in FIG. 2C are for illustration purposes only, and any suitable shapes and sizes can be used for the dielectric sections 201A-201D, the dielectric sections 203A-203D, and the central dielectric section 234, respectively.

In some examples, one or more layers in the gate dielectric structures 230 can be separated, and thus can have an open-loop configuration. FIG. 2D is a top-down view showing a cross-section of an example (also referred to as a channel structure 18(3)) of the channel structure 18 that is perpendicular to the vertical axis B-B′. The channel structure 18(3) can include a gate dielectric structure 238, the channel layer that includes the channel layer sections 206A-206D, and a channel dielectric structure 224.

Similar to the channel structure 18(1), the gate dielectric structure 238 in the channel structure 18(3) includes the barrier layer 212 and the charge trapping layer 210. Differences between the channel structures 18(1) and 18(3) are described below. In FIG. 2D, the gate dielectric structure 238 includes a tunneling layer (or discontinuous tunneling layer) that has multiple tunneling layer sections 218A-218D with an open-loop configuration. In FIG. 2A, the gate dielectric structure 230 includes the closed-loop tunneling layer (or continuous tunneling layer) 208.

In FIG. 2D, in addition to separating the multiple channel layer sections 206A-206D, dielectric sections 231A-231D in the channel dielectric structure 224 also separate the multiple tunneling layer sections 218A-218D, respectively. The inner surface 243 in FIG. 2A is separated into inner surfaces 258. The dielectric sections 231A-231D can be arranged along the inner surface 242 of the charge trapping layer 210. In FIG. 2A, the dielectric sections 201A-201D separate the multiple channel layer sections 206A-206D, and does not separate the closed-loop tunneling layer 208.

Referring to FIG. 2D, a first MC string can be formed based on the channel layer section 206A, the top channel contact 214A, the barrier layer 212, the charge trapping layer 210, and the tunneling layer section 218A. A second MC string can be formed based on the channel layer section 206B, the top channel contact 214B, the barrier layer 212, the charge trapping layer 210, and tunneling layer section 218B. A third MC string can be formed based on the channel layer section 206C, the top channel contact 214C, the barrier layer 212, the charge trapping layer 210, and tunneling layer section 218C. A fourth MC string can be formed based on the channel layer section 206D, the top channel contact 214D, the barrier layer 212, the charge trapping layer 210, and tunneling layer section 218D. By introducing the open-loop configuration into the tunneling layer having the multiple tunneling layer sections 218A-218D, data disturbing can be prevented in the first, second, third, and fourth MC strings and device reliabilities can be improved in the 3D semiconductor device 100 where the channel structure 18 is the channel structure 18(3).

FIG. 2E is a top-down view showing a cross-section of an example (also referred to as a channel structure 18(4)) of the channel structure 18 that is perpendicular to the vertical axis B-B′. The channel structure 18(4) can include a gate dielectric structure 238′, the channel layer that includes the channel layer sections 206A-206D, and the channel dielectric structure 224.

Similar to the channel structure 18(3), the gate dielectric structure 238′ in the channel structure 18(4) includes the barrier layer 212 and the discontinuous tunneling layer that has the multiple tunneling layer sections 218A-218D. Differences between the channel structures 18(3) and 18(4) are described below. In FIG. 2E, the gate dielectric structure 238′ includes a charge trapping layer (or a discontinuous charge trapping layer) that has multiple charge trapping layer sections 220A-220D with an open-loop configuration and inner surfaces 268. In FIG. 2D, the gate dielectric structure 238 includes the closed-loop charge trapping layer (or continuous charge trapping layer) 210.

In FIG. 2D, the dielectric sections 231A-231D separate the multiple channel layer sections 206A-206D and the multiple tunneling layer sections 218A-218D. In FIG. 2E, in addition to separating the multiple channel layer sections 206A-206D and the multiple tunneling layer sections 218A-218D, dielectric sections 231A′-231D′ in the channel dielectric structure 224 also separate the multiple charge trapping layer sections 220A-220D, respectively. The dielectric sections 231A′-231D′ can be arranged along the inner surface 241 of the barrier layer 212.

Referring to FIG. 2E, a first MC string can be formed based on the channel layer section 206A, the top channel contact 214A, the barrier layer 212, the charge trapping layer section 220A, and the tunneling layer section 218A. A second MC string can be formed based on the channel layer section 206B, the top channel contact 214B, the barrier layer 212, the charge trapping layer section 220B, and tunneling layer section 218B. A third MC string can be formed based on the channel layer section 206C, the top channel contact 214C, the barrier layer 212, the charge trapping layer section 220C, and tunneling layer section 218C. A fourth MC string can be formed based on the channel layer section 206D, the top channel contact 214D, the barrier layer 212, the charge trapping layer section 220D, and tunneling layer section 218D. By introducing the open-loop configuration into the tunneling layer having the multiple tunneling layer sections 218A-218D and into the charge trapping layer having the multiple charge trapping layer sections 220A-220D, data disturbing can be further prevented in the first, second, third, and fourth MC strings and device reliabilities can be improved in the 3D semiconductor device 100 where the channel structure 18 is the channel structure 18(4).

As described above, the cross-section of the sidewall 240 (or the cross-section of the channel hole) and the cross-section of the channel structure 18 (e.g., one of 18(1)-(4)) can have various profiles, such as an oval profile, a trefoil profile, a quatrefoil profile, a star profile, and the like.

FIG. 2F is a top-down view showing a cross-section of an example (referred to as a channel structure 18(5)) of the channel structure 18 that is perpendicular to the vertical axis B-B′ according to an embodiment of the disclosure. The channel structure 18(5) is similar to the channel structure 18(1) except that the cross-section of the channel structure 18(5) has an oval profile, and thus detailed descriptions for the channel structure 18(5) are omitted for purposes of brevity. The differences between the channel structure 18(5) and the channel structure 18(1) are described below.

Referring to FIG. 2F, the cross-section of the sidewall 240 (or the cross-section of the channel hole) can be mirror symmetric and include two axes of symmetry, such as a short axis C-C′ and a long axis D-D′ of the cross-section of the sidewall 240.

The two channel layer sections 206A and 206C can be arranged at opposing ends of one (e.g., the long axis D-D′) of the two axes of symmetry. Dielectric sections 233A and 233C of the channel dielectric structure 204 can separate the multiple channel layer sections 206A and 206C. The channel layer including the two channel layer sections 206A and 206C has the open-loop configuration, and the gate dielectric structure 230 has the closed-loop configuration. The channel structure 18(5) shows a two-phase split cell configuration (e.g., two-phase split MC configuration) where two separate cells (e.g., two separate MCs) can be formed based on the channel structure 18(5) (e.g., the channel layer sections 206A and 206C). The channel layer including the separated channel layer sections 206A and 206C has a split channel configuration.

Accordingly, two MC strings can be formed based on the channel structure 18(5) and the gate structures 312. The two MC strings can be formed based on the respective channel layer sections 206A and 206C, the gate dielectric structure 230, and the gate structures 312. For example, a first MC string is formed based on the channel layer section 206A and a second MC string is formed based on the channel layer section 206C. Thus, the bit density of the 3D semiconductor device 100 can be doubled as compared to a device having a closed-loop channel layer and a gate dielectric structure that is identical to the gate dielectric structure 230.

Points C, C′, D, and D′ are intercepts of the axes C-C′ and D-D′ with the sidewall 240. First distances OC and OC′ can be smallest among distances between the point O and respective points on the cross-section of the sidewall 240. Second distances OD and OD′ can be largest among the distances between the point O and respective points on the cross-section of the sidewall 240. The first distances OC and OC′ are shorter than the second distances OD and OD′. Similarly, a distance CC′ along the short axis C-C′ is shorter than a distance DD′ along the long axis D-D′. A ratio of one (e.g., OD) of the second distances over one (e.g., OC) of the first distances can be larger than 1, such as in a range of 1.5 to 2. In an example, the cross-sections of the sidewall 240 and the channel structure 18(5) are symmetric with respect to the point O. Thus, the first distances OC and OC′ can be identical and the second distances OD and OD′ can be identical.

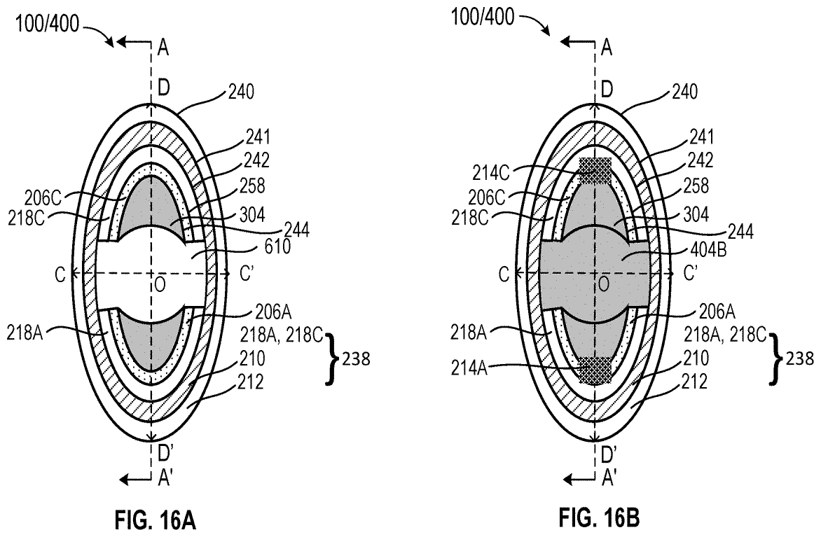

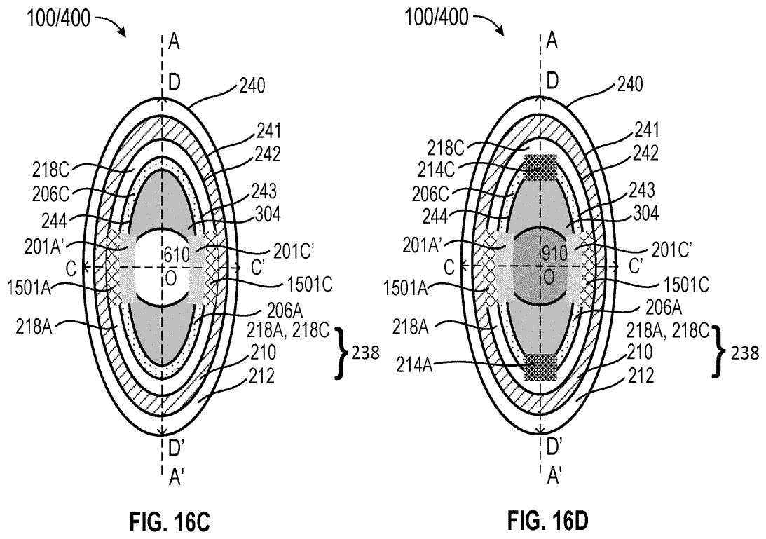

The channel dielectric structure 204 can include any suitable dielectric material(s). Distribution of the dielectric material(s) in the channel dielectric structure 204 can be uniform (e.g., as shown in FIG. 2F) or non-uniform (e.g., as shown below in FIG. 16A. FIG. 16A shows an example of the channel structure 18(5) where the channel dielectric structure 204 includes different dielectric materials.

According to aspects of the disclosure, one or more layers in the gate dielectric structures 230 shown in FIG. 2F can be separated, and thus can have an open-loop configuration. FIG. 2G is a top-down view showing a cross-section of an example (also referred to as a channel structure 18(6)) of the channel structure 18 that is perpendicular to the vertical axis B-B′. The channel structure 18(6) can include the gate dielectric structure 238, the channel layer that includes the channel layer sections 206A and 206C, and a channel dielectric structure 225.

Similar to the channel structure 18(5), the gate dielectric structure 238 in the channel structure 18(6) includes the barrier layer 212 and the charge trapping layer 210. Differences between the channel structures 18(5)-18(6) are described below. In FIG. 2G, the gate dielectric structure 238 includes a tunneling layer (or discontinuous tunneling layer) that has two tunneling layer sections 218A and 218C with an open-loop configuration. In FIG. 2F, the gate dielectric structure 230 includes the closed-loop tunneling layer (or continuous tunneling layer) 208.

In FIG. 2G, in addition to separating the two channel layer sections 206A and 206C, dielectric sections 232A and 232C in the channel dielectric structure 225 also separate the two tunneling layer sections 218A and 218C and inner surfaces 258 of the two tunneling layer sections 218A and 218C. The dielectric sections 232A and 232C can be arranged along the inner surface 242 of the charge trapping layer 210. In FIG. 2F, the dielectric sections 233A and 233C separate the two channel layer sections 206A and 206C, and does not separate the closed-loop tunneling layer 208.

Referring to FIG. 2G, a first MC string can be formed based on the channel layer section 206A, the top channel contact 214A, the barrier layer 212, the charge trapping layer 210, and the tunneling layer section 218A. A second MC string can be formed based on the channel layer section 206C, the top channel contact 214C, the barrier layer 212, the charge trapping layer 210, and tunneling layer section 218C. By introducing the open-loop configuration into the tunneling layer having the tunneling layer sections 218A and 218C, disturbance between the MC strings can be prevented in the first and second MC strings and device reliability can be improved in the 3D semiconductor device 100 where the channel structure 18 is the channel structure 18(6).

FIG. 2H is a top-down view showing a cross-section of an example (also referred to as a channel structure 18(7)) of the channel structure 18 that is perpendicular to the vertical axis B-B′. The channel structure 18(7) can include a gate dielectric structure 238′, the channel layer that includes the channel layer sections 206A and 206C, and a channel dielectric structure 226.

Similar to the channel structure 18(6), the gate dielectric structure 238′ in the channel structure 18(7) includes the barrier layer 212 and the discontinuous tunneling layer that has the tunneling layer sections 218A and 218C. Differences between the channel structures 18(6) and 18(7) are described below. In FIG. 2H, the gate dielectric structure 238′ includes a charge trapping layer (or a discontinuous charge trapping layer) that has two charge trapping layer sections 220A and 220C with an open-loop configuration and inner surfaces 268. In FIG. 2G, the gate dielectric structure 238 includes the closed-loop charge trapping layer (or continuous charge trapping layer) 210.

In FIG. 2H, in addition to separating the channel layer sections 206A and 206C and the tunneling layer sections 218A and 218C, dielectric sections 232A′ and 232C′ in the channel dielectric structure 226 also separate the charge trapping layer sections 220A and 220C. The dielectric sections 232A′ and 232C′ can be arranged along the inner surface 241 of the barrier layer 212.

Referring to FIG. 2H, a first MC string can be formed based on the channel layer section 206A, the top channel contact 214A, the barrier layer 212, the charge trapping layer section 220A, and the tunneling layer section 218A. A second MC string can be formed based on the channel layer section 206C, the top channel contact 214C, the barrier layer 212, the charge trapping layer section 220C, and tunneling layer section 218C. By introducing the open-loop configuration into the tunneling layer having the tunneling layer sections 218A and 218C and into the charge trapping layer having the charge trapping layer sections 220A and 220C, disturbance between the MC strings can be further prevented in the first and second MC strings and device reliability can be improved in the 3D semiconductor device 100 where the channel structure 18 is the channel structure 18(7).

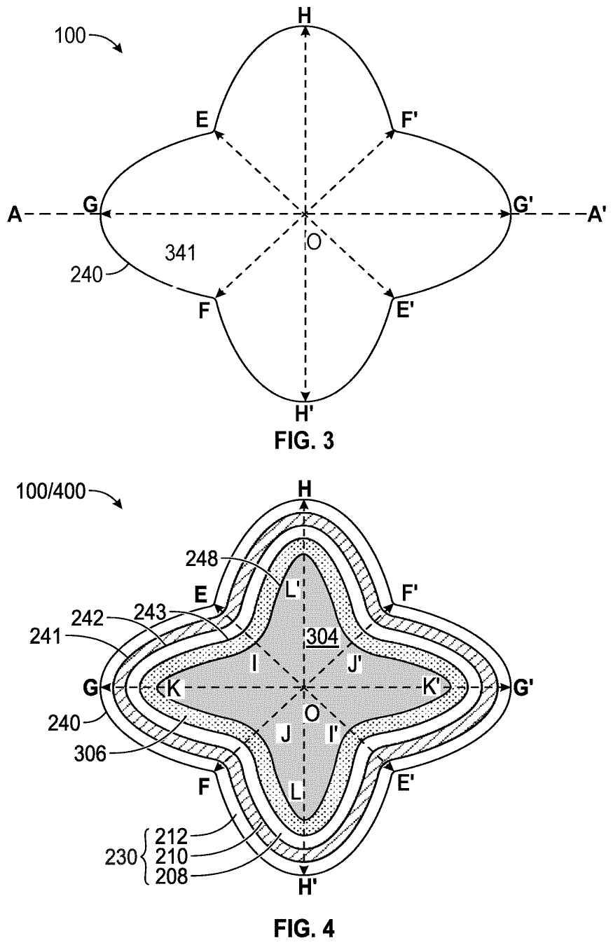

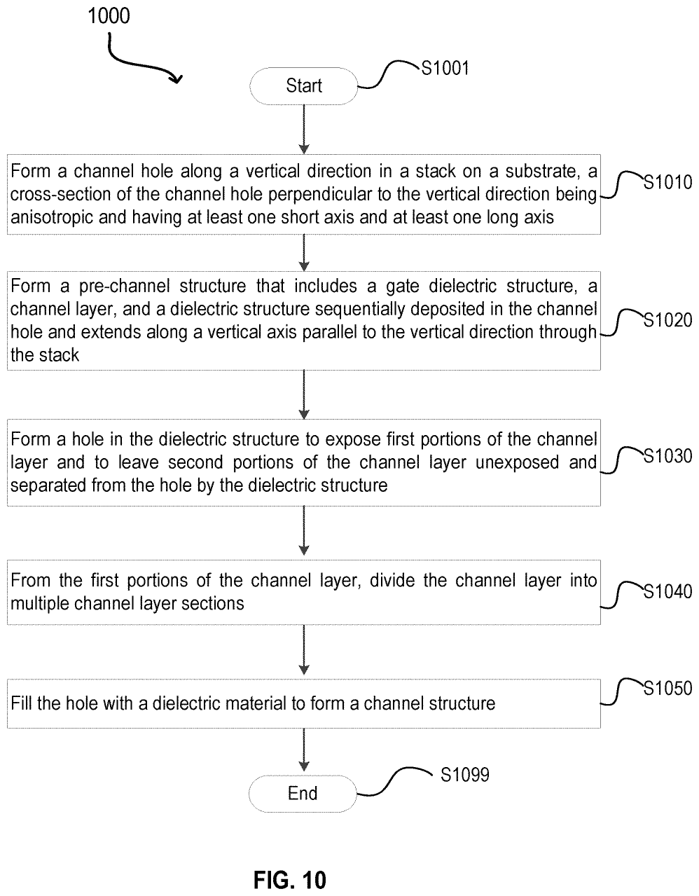

FIGS. 3-6, 7A-7C, 8A-8C, and 9A-9C show top-down views of cross-sections of various steps of manufacturing a 3D semiconductor device (e.g., the 3D semiconductor device 100 including the channel structure 18) according to aspects of the disclosure. FIG. 10 shows a flowchart of a process 1000 for manufacturing the 3D semiconductor device 100 according to an embodiment of the disclosure. The process 1000 can be used to form the 3D semiconductor device including a channel structure where the channel structure can have any suitable shape or profile, such as an oval profile, a trefoil profile, a quatrefoil profile, a star profile, and the like.

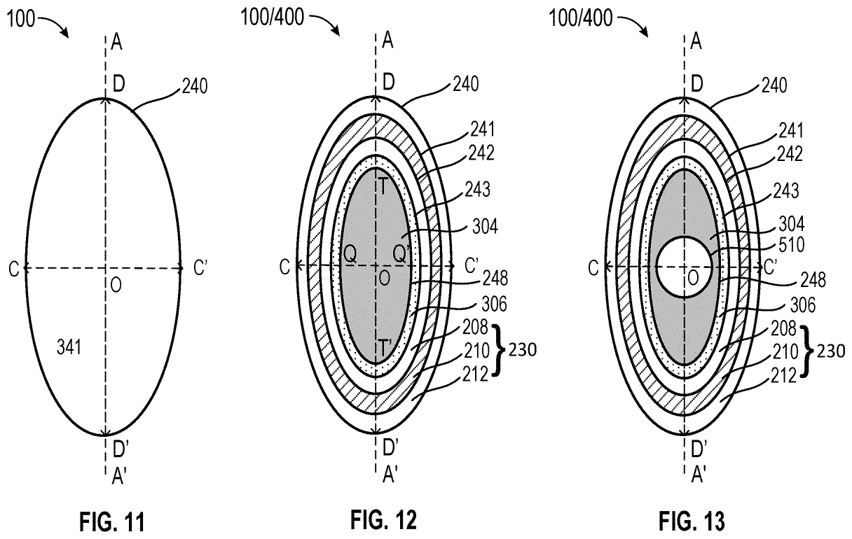

For illustration purposes, FIGS. 3-6, 7A-7C, 8A-8C, and 9A-9C show exemplary channel structures having the quatrefoil profile. FIGS. 11-14, 15A-15D, 16A-16B, and 17A-17B show top-down views of cross-sections of various steps of manufacturing the 3D semiconductor device including exemplary channel structures having the oval profile. Detailed descriptions for manufacturing the 3D semiconductor device 100 with the oval profile (e.g., FIGS. 11-14, 15A-15D, 16A-16B, and 17A-17B) are omitted for purposes of brevity. Differences between manufacturing the 3D semiconductor device 100 with the quatrefoil profile and the oval profile are described.

The process 1000 starts at S1001 and proceeds to S1010. Referring to FIGS. 3 and 10, at S1010, a channel hole 341 including the sidewall 240 can be formed along the vertical direction in the stack that includes the plurality of gate line layers 12 and the plurality of insulating layers 14 on the substrate 10 through a patterning process. The patterning process can include a photolithograph process and an etching process that etch the alternating gate line layers 12 and the insulating layers 14.

In general, the channel hole 341 can extend through the stack along the vertical direction. The cross-section of the sidewall 240 (also the cross-section of the channel hole) perpendicular to the vertical direction can have any suitable anisotropic profile (e.g., an oval profile shown in FIG. 11, a trefoil profile, a quatrefoil profile, a star profile, or the like). The cross-section of the sidewall 240 can have the plurality of axes of symmetry (e.g., E-E′, F-F′, G-G′, and H-H′) as described above. The plurality of axes of symmetry can intersect at a center point (e.g., the point O) of the sidewall 240. A first distance (e.g., OE) is smallest among distances between the center point (e.g., the point O) and respective points on the sidewall 240 of the cross-section of the channel hole 341. The first distance (e.g., OE) can be along a first one (e.g., the axis E-E′) of the plurality of axes of symmetry. A second distance (e.g., OH) is largest among the distances and the second distance can be along a second one (e.g., H-H′) of the plurality of axes of symmetry. The second distance can be larger than the first distance.

In an example, the cross-section of the sidewall 240 has the at least one short axis and the at least one long axis, as described above with reference to FIG. 2A. In an example, the at least one axis includes the axes E-E′ and F-F′ and the at least one long axis includes the axes G-G′ and H-H′. Thus, the ratio of the second distance (e.g., OH) over the first distance (e.g., OE) can be larger than 1, such as in a range of 1.5 to 2. A ratio of a distance HH′ over a distance of EE′ can be larger than 1, such as in a range of 1.5 to 2. In an example, the cross-section of the sidewall 240 has a quatrefoil profile and is mirror symmetric having the plurality of axes of symmetry as described with reference to FIG. 2A.

Referring to FIGS. 10 and 11, at S1010, the channel hole 341 of the 3D semiconductor device 100 including the sidewall 240 can have the oval profile having the long axis D-D′ and the short axis C-C′.

Referring to FIGS. 4 and 10, at S1020, a pre-channel structure 400 can be formed in the channel hole 341 and extend along the vertical axis B-B′ through the stack. The pre-channel structure 400 can have the gate dielectric structure 230 and a channel layer 306 that are concentrically arranged around the vertical axis B-B′. The channel layer 306 can have a closed-loop configuration. The gate dielectric structure 230 can include the barrier layer 212, the charge trapping layer 210, and the tunneling layer 208 that are concentrically arranged around the vertical axis B-B′, as described above.

The barrier layer 212 can be conformably formed along the sidewall 240 of the channel hole 341 where the barrier layer 212 can be concentrically positioned around the vertical axis B-B′ and in direct contact with the plurality of gate structures 312 and the plurality of insulating layers 14. The charge trapping layer 210 can be conformably formed over the inner surface 241 of the barrier layer 212. The tunneling layer over 208 can be conformably formed over the inner surface 242 of the charge trapping layer 210. The channel layer 306 can be conformably formed over the inner surface 243 of the tunneling layer 208. Further, a dielectric structure 304 can be formed over an inner surface 248 of the channel layer 306. The dielectric structure 304 can completely or partially fill the channel hole 341. Various deposition processes can be used to form the gate dielectric structure 230, the channel layer 306, and the dielectric structure 304.

A cross-section of the pre-channel structure 400 perpendicular to the vertical axis B-B′ can have an anisotropic profile. Referring to FIG. 4, the anisotropic profile of the pre-channel structure 400 can be identical to that of the channel hole 341 (or the sidewall 240). In an example, a cross-section of the channel layer 306 perpendicular to the vertical axis B-B′ can have an anisotropic profile that is identical or similar to that of the channel hole 341 (or the sidewall 240) as the gate dielectric structure 230 and the channel layer 306 can be conformably formed by sequentially depositing the barrier layer 212, the charge trapping layer 210, the tunneling layer 208, and the channel layer 306 over the sidewall 240. The cross-section of the channel layer 306 can be mirror symmetric and include axes of symmetry that are parallel to the respective axes of symmetry of the cross-section of the sidewall 240. The cross-section of the channel layer 306 can include the at least one short axis (e.g., the axes E-E′ (or I-I′) and F-F′ (or J-J′)) and the at least one long axis (e.g., the axes G-G′ (or K-K′) and H-H′ (or L-L′)). The axes I-I′, J-J′, K-K′, and L-L′ intersect with the inner surface 284 at points I, I′, J, J′, K, K′, L, and L′, respectively.

When the cross-sections of the sidewall 240 and the channel layer 306 are mirror symmetric, the distances EE′ and FF′ are identical, the distances II′ and JJ′ are identical, the distances GG′ and HH′ are identical, and the distances KK′ and LL′ are identical. Further, distances OI, OJ, and OJ′ are identical, distances OK, OK′, OL, and OL′ are identical, distances OE, OE′, OF, and OF′ are identical, and distances OG, OG′, OH, and OH′ are identical. A first ratio of one of the distances OK, OK′, OL, and OL′ over one of the distances OI, OJ, and OJ′ can be larger than 1, such as in a range of 1.5 to 2. In an example, the first ratio is identical to the ratio of the second distance (e.g., the distance OH) over the first distance (e.g., the distance OE).

Referring to FIGS. 10 and 12, at S1020, the pre-channel structure 400 can have the oval profile. Thus, the gate dielectric structure 230 and the channel layer 306 can have the oval profile. The cross-section of the channel layer 306 can include the short axis C-C′ and the long axis D-D′. The axes C-C′ and D-D′ intersect with the inner surface 248 at points Q, Q′, T, and T′, respectively.

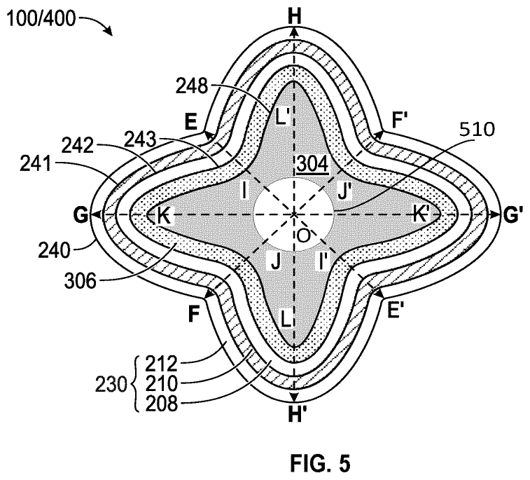

Referring to FIGS. 5 and 10, at S1030, an etching process (e.g., a first etching process), such as a dry etching process, can be applied to form a hole 510 in the dielectric structure 304. A size of the hole 510 can be controlled such that a cross-section of the hole 510 perpendicular to the vertical axis B-B′ is within the cross-section of the channel layer 306. For example, the hole 510 has a cylindrical shape, and thus the cross-section of the hole 510 is a circle. A diameter of the circle can be less than or equal to the distances II′ and JJ′. Alternatively, a radius of the circle can be less than or equal to the distances OI, OJ, and OJ′. An etching mask can be used to form the hole 510, and a size of the etching mask can be substantially identical to the size of the hole 510.

Referring to FIGS. 10 and 13, at S1030, the hole 510 can be formed in the dielectric structure 304. Similarly, the diameter of the circle can be less than or equal to a distance QQ′.

In an example, the channel layer 306 is completely covered by the dielectric structure 304, for example, when the diameter of the circle (or the hole 510) is less than the distances II′ and JJ′ in FIG. 5 or the distance QQ′ in FIG. 13. Thus, the hole 510 is separated from the channel layer 306 by the dielectric structure 304.

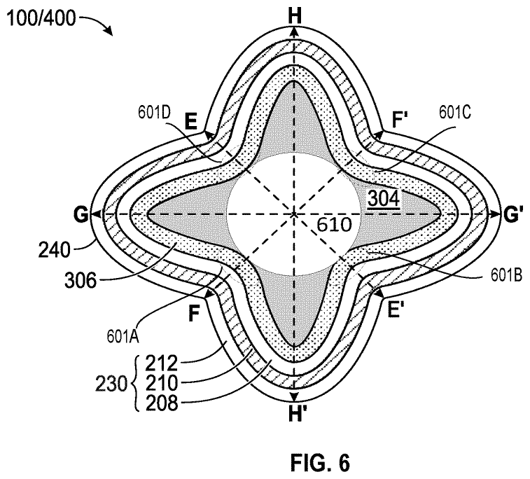

A second etching process can be used. Referring to FIGS. 5-6, at S1030, the hole 510 is further enlarged by the etching process into a hole 610 where portions of the dielectric structure 304 around or adjacent to first portions 601A-601D of the channel layer 306 can be removed. The first portions 601A-601D of the channel layer 306 can be partially or substantially co-located with the dielectric sections 201A-201D, respectively. Accordingly, the first portions 601A-601D of the channel layer 306 can be exposed or uncovered by the hole 610, and remaining portions (or second portions) of the channel layer 306 can be covered by the remaining dielectric structure 304. Thus, the second portions of the channel layer 306 are separated from the hole 610 by the remaining dielectric structure 304. The anisotropic profile of the channel layer 306 can facilitate the exposure of the first portions 601A-601D of the channel layer 306 and the coverage of the second portions of the channel layer 306. In an example shown in FIGS. 5-6, the first portions 601A-601D of the channel layer 306 are around or adjacent to the at least one short axis (e.g., the short axes E-E′ and F-F′), and the second portions of the channel layer 306 are around or adjacent to the long axes G-G′ and H-H′.

The etching mask used to form the hole 510 can be removed prior to the second etching process, and the second etching process to form the hole 610 can be a blank etching process without an etching mask. The second etching process can be selective, and thus selectively etching the dielectric structure 304 (e.g., silicon oxide) while not etching or minimally etching the channel layer 306 (e.g., polysilicon). The second etching process can include a dry etching process, a wet etching process, or a combination of dry and wet etching processes. Etching conditions (e.g., an etching duration, temperature, an etching type) of the second etching process can be controlled so that the first portions 601A-601D of the channel layer 306 is minimally affected by the second etching process.

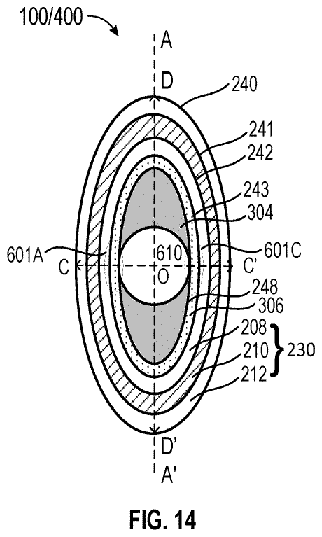

Similarly, referring to FIGS. 10 and 14, at S1030, the hole 510 can be further enlarged by the second etching process to form the hole 610 where portions of the dielectric structure 304 around or adjacent to first portions 601A and 601C of the channel layer 306 can be removed. The etching conditions of the second etching process can be controlled so that the first portions 601A and 601C of the channel layer 306 is minimally affected by the second etching process.

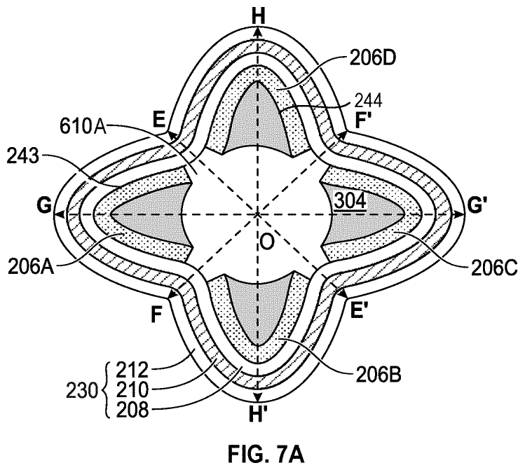

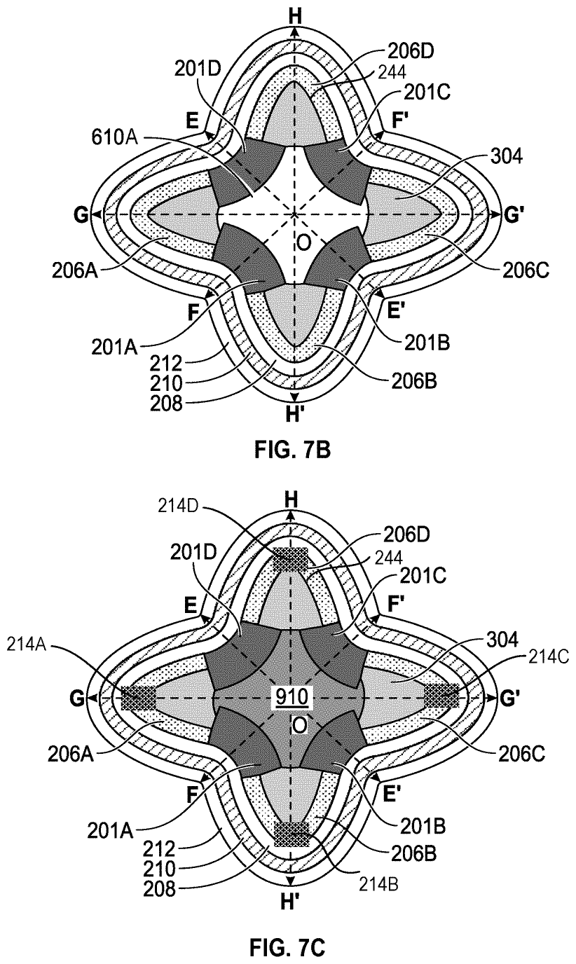

Referring to FIG. 10, at S1040, the channel layer 306 can be divided or separated into the channel layer sections 206A-206D based on the first portions 601A-601D of the channel layer 306. In an example, referring to FIGS. 6 and 7A, the channel layer 306 can be divided into the channel layer sections 206A-206D by removing third portions of the channel layer 306 that are co-located with the first portions 601A-601D using an etching process. Thus, the inner surface 248 of the channel layer 306 becomes inner surfaces 244 of the channel layer sections 206A-206D. In an example, the third portions of the channel layer 306 include the first portions 601A-601D of the channel layer 306. In an example, the third portions of the channel layer 306 are included in the first portions 601A-601D of the channel layer 306. Thus, the closed-loop channel layer 306 becomes the open-loop channel layer including the channel layer sections 206A-206D. By controlling etching conditions, such as an etching duration, the third portions of the channel layer 306 can be removed, and remaining portions (or fourth portions) of the channel layer 306 can remain and become the channel layer sections 206A-206D. Thus, the closed-loop channel layer 306 can be etched into the open-loop channel layer including the channel layer sections 206A-206D. The hole 610 can include voids corresponding to the removed third portions of the channel layer. In an example, the hole 610 is thus enlarged along the at least one short axis (e.g., the short axes E-E′ and F-F′) and portions of the inner surface 243 of the tunneling layer 208 can be exposed.

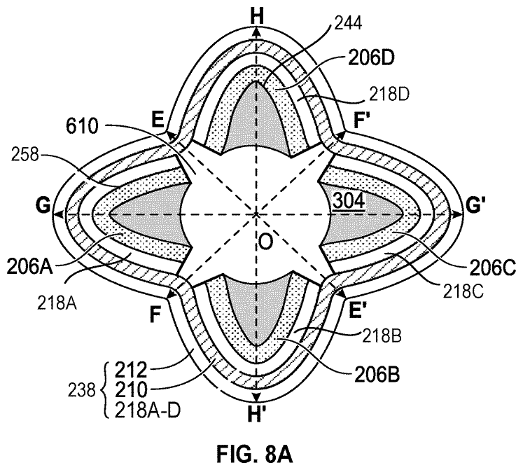

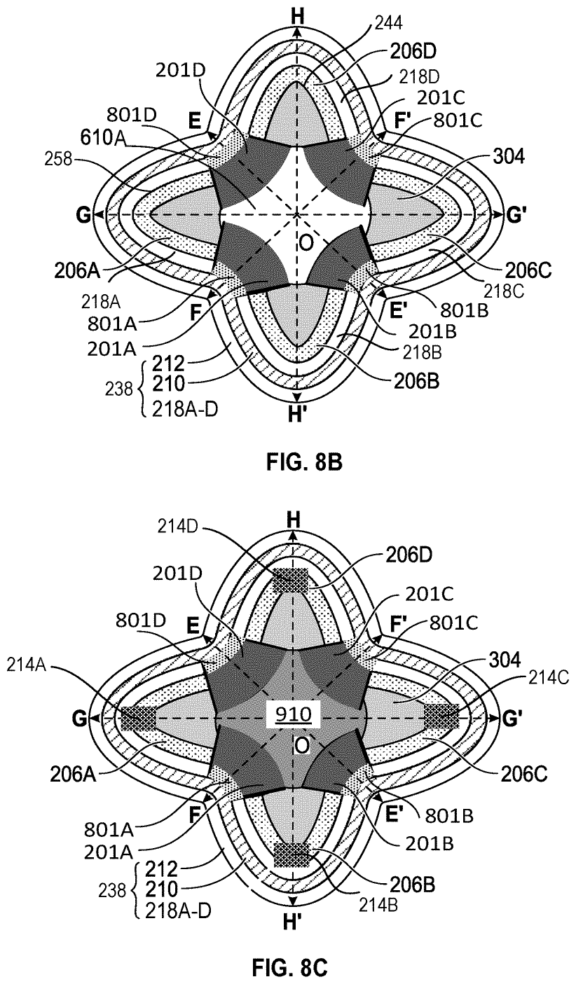

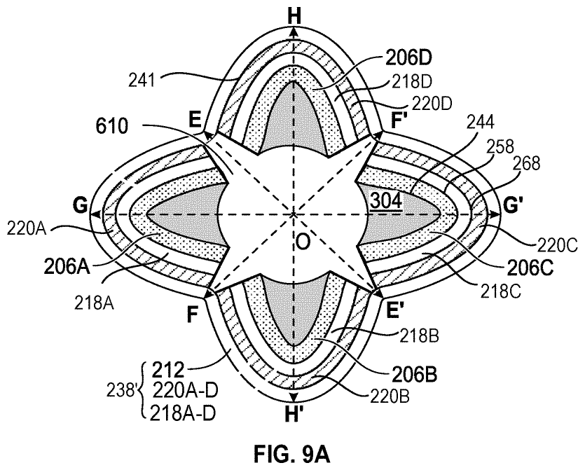

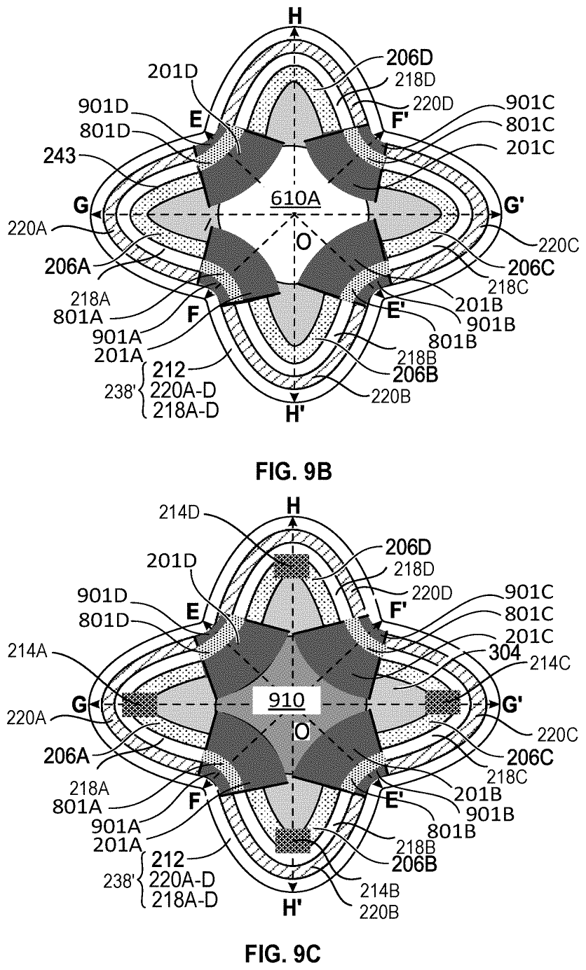

In an example, the tunneling layer 208 is minimally affected by the etching process in FIG. 7A and remains a closed-loop configuration. In an example, referring to FIG. 8A, the tunneling layer 208 is further etched to have an open-loop configuration by an etching process to form the tunneling layer sections 218A-D with the inner surfaces 258. The tunneling layer sections 218A-D can correspond to the respective channel layer sections 206A-D. In an example, referring to FIG. 9A, the tunneling layer 208 in FIG. 6 is further etched to have an open-loop configuration by an etching process to form the tunneling layer sections 218A-D. Further, the charge trapping layer 210 is further etched to have an open-loop configuration by an etching process to form the charge trapping layer sections 220A-D where the gate dielectric structure 238′ includes the tunneling layer sections 218A-D with the inner surfaces 258, the charge trapping layer sections 220A-D with the inner surfaces 268, and the barrier layer 212. The charge trapping layer sections 220A-D can correspond to the respective tunneling layer sections 218A-D.

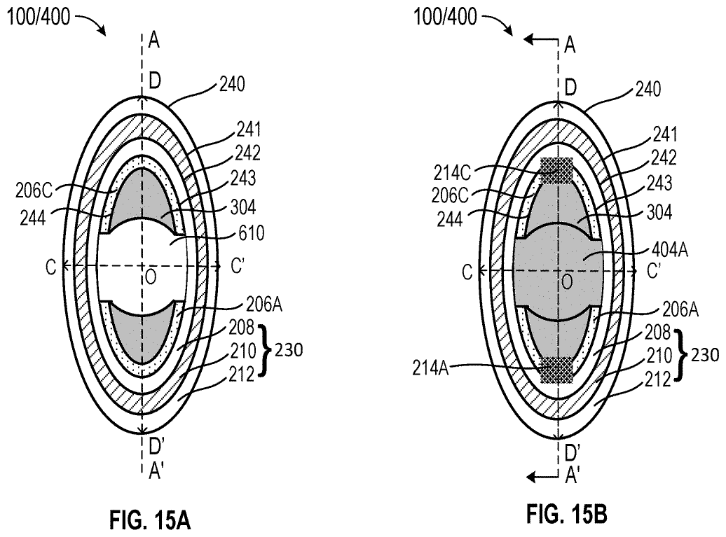

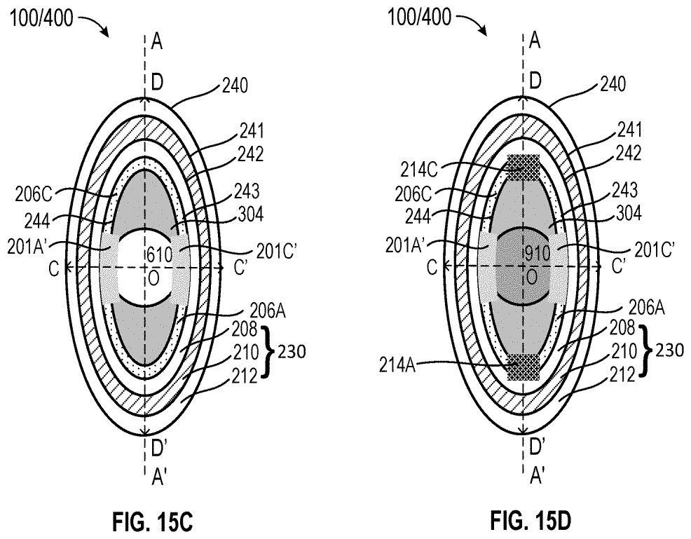

The above descriptions can be adapted to FIGS. 15A, 16A, and 17A for the oval profile. Referring to FIG. 15A, 16A, and 17A, the channel layer 306 can be divided into the channel layer sections 206A and 206C by removing third portions of the channel layer 306 that are co-located with the first portions 601A and 601C using the etching process.

In an example, referring to FIG. 15A, the tunneling layer 208 is minimally affected by the etching process and remains the closed-loop configuration.

In an example, referring to FIG. 16A, the tunneling layer 208 is further etched to have an open-loop configuration by an etching process to form the tunneling layer sections 218A and 218C and thus forming the gate dielectric structure 238.

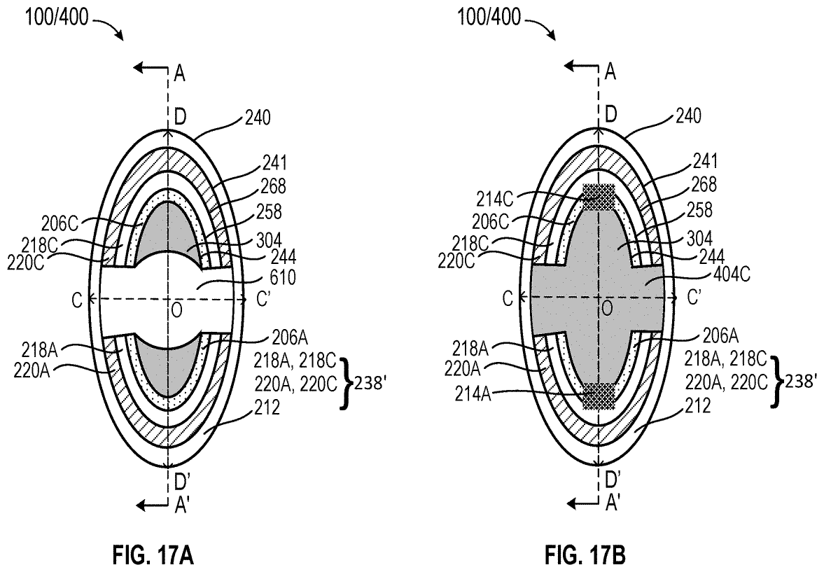

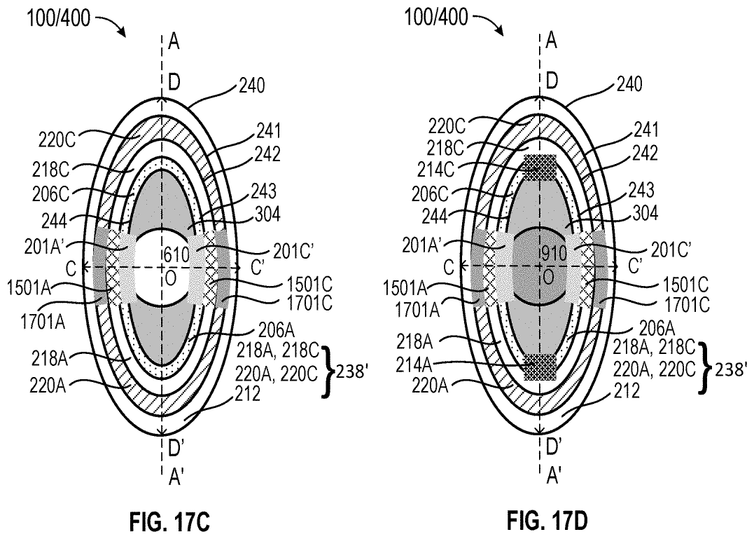

In an example, referring to FIG. 17A, the tunneling layer 208 in FIG. 14 is further etched to have an open-loop configuration by an etching process to form the tunneling layer sections 218A and 218C. The charge trapping layer 210 is further etched to have an open-loop configuration by an etching process to form the charge trapping layer sections 220A and 220C where the gate dielectric structure 238′ includes the tunneling layer sections 218A and 218C, the charge trapping layer sections 220A and 220C, and the barrier layer 212.

Referring to FIGS. 2A, 7A, and 10, at S1050, a dielectric material can be deposited to fill the hole 610 in FIG. 7A. The deposition process can be similar to that used in forming the dielectric structure 304. The dielectric material deposited in the voids can be disposed between adjacent ones of the channel layer sections 206A-206D.

In an example, the dielectric material deposited at S1050 can be made of same material(s) as those of the dielectric structure 304, such as silicon oxide. Thus, the channel dielectric structure 204 can be formed from the dielectric material deposited at S1050 and the remaining dielectric structure 304, and the channel structure 18(1) can be formed.

In an example, the dielectric material deposited at S1050 can be different from those of the dielectric structure 304. The channel dielectric structure 204 can be formed from the dielectric material deposited at S1050 (e.g., the first dielectric material) and the remaining dielectric structure 304 (e.g., the second dielectric material), and the channel structure 18(2) can be formed.

Similarly, referring to FIGS. 8A and FIG. 10, at S1050, a dielectric material can be deposited to fill the hole 610 in FIG. 8A. The dielectric material that fills the hole 610 can be identical to or different from that used in the dielectric section 304. In an example, the dielectric material is identical to that used in the dielectric section 304 and thus the channel structure 18(3) in FIG. 2D can be formed where the dielectric section 224 includes the dielectric section 304 and the dielectric material filling the hole 610.

Similarly, referring to FIGS. 9A and FIG. 10, at S1050, a dielectric material can be deposited to fill the hole 610 in FIG. 9A. The dielectric material filling the hole 610 can be identical to or different from that used in the dielectric section 304. In an example, the dielectric material is identical to that used in the dielectric section 304 and thus the channel structure 18(4) in FIG. 2E can be formed where the dielectric section 224 includes the dielectric section 304 and the dielectric material filling the hole 610.

Similarly, for the oval profile, referring to FIGS. 10, 15A, and 15B, at S1050, a dielectric material can be deposited to fill the hole 610 in FIG. 15A and form a dielectric section 404A in FIG. 15B, and thus the channel structure 400 in FIG. 15B can be formed. The dielectric materials in the dielectric section 404A and the dielectric structure 304 can be different (e.g., shown in FIG. 15B) or identical (e.g., shown as the dielectric structure 204 in FIG. 2F where the dielectric structure 204 includes the dielectric structure 304 and the dielectric section 404A).

FIG. 15B shows an example of the channel structure where the channel dielectric structure 204 includes different dielectric materials, such as at least a first dielectric material and a second dielectric material that is different from the first dielectric material, and the different dielectric materials (e.g., the first dielectric material and the second dielectric material) are distributed at different locations (304 and 404A) within the channel dielectric structure 204.

Similarly, for the oval profile, referring to FIGS. 10, 16A, and 16B, at S1050, a dielectric material can be deposited to fill the hole 610 and form a dielectric section 404B in FIG. 16B, and thus the channel structure 400 in FIG. 16B can be formed. The dielectric materials in the dielectric section 404B and the dielectric structure 304 can be different (e.g., shown in FIG. 16B) or identical (e.g., shown as the dielectric structure 204 in FIG. 2G).

Similarly, for the oval profile, referring to FIGS. 10, 17A, and 17B, at S1050, a dielectric material can be deposited to fill the hole 610 and form a dielectric section 404C in FIG. 17B, and thus the channel structure 400 in FIG. 17B can be formed. The dielectric materials in the dielectric section 404C and the dielectric structure 304 can be different (e.g., shown in FIG. 17B) or identical (e.g., shown as the dielectric structure 204 in FIG. 2H).

As described above, at S1040, the channel layer 306 can be divided or separated into the channel layer sections 206A-206D based on the first portions 610A-601D of the channel layer 306 (e.g., adjacent to the at least one short axis (e.g., the axes E-E′ and F-F′)). In the descriptions above with reference to FIG. 7A, the etching process is used to implement S1040.

A different process can be used to implement S1040. Referring to FIG. 7B, at S1040, the channel layer 306 can be divided into the channel layer sections 206A-206D by replacing conductive material(s) (e.g., polysilicon) of the third portions of the channel layer 306 (e.g., adjacent to the at least one short axis (e.g., the axes E-E′ and F-F′)) with a dielectric material or an oxidized material (e.g., silicon oxide) that is disposed between adjacent ones of the channel layer sections 206A-206D. The oxidized material can form the dielectric sections 201A-201D. Thus, the third portions of the channel layer 306 can be replaced with the dielectric sections 201A-201D. In an example, an oxidation process, such as polysilicon oxidation, is used to oxidize the third portions of the channel layer 306 from polysilicon to silicon oxide. The dielectric material (e.g., silicon oxide) in the dielectric sections 201A-201D can be identical to or different from the dielectric material(s) used in the dielectric structure 304, as described above with reference to FIGS. 2A and 2C. As described above, at least two different methods can be used to separate the closed-loop channel layer 306 into the channel layer sections 206A-206D.

Subsequently, referring to FIG. 7C, at S1050, the dielectric material can be deposited to fill the hole 610A and thus form a dielectric section 910, as described above. In an example, the channel structure 18(2) can be formed where the dielectric material (e.g., the first dielectric material) in the dielectric sections 201A-201D are different from other portions (e.g., the second dielectric material) in the channel dielectric structure 204. Referring to FIGS. 2C and 7C, the dielectric section 910 in FIG. 7C corresponds to the central dielectric section 234 in FIG. 2C and the remaining portions of the dielectric structure 304 in FIG. 7C can include the dielectric sections 203A-203D in FIG. 2C. The dielectric material(s) in 910, the dielectric sections 201A-D, and the remaining portions of the dielectric structure 304 can be different or identical. Alternatively, the channel structure 18(1) can be formed where the dielectric material in the dielectric sections 201A-201D are identical to the other portions in the channel dielectric structure 204.

Referring to FIGS. 8B and 9B, the tunneling layer 208 and/or the charging trapping layer 210 can be further separated, for example, by oxidation process(es) after the channel layer 306 is separated, for example, by the oxidation process shown in FIG. 7B. After replacing the third portions of the channel layer 306 with the dielectric sections 201A-201D as shown in FIG. 7B, portions of the tunneling layer 208 that are adjacent to the dielectric sections 201A-201D can be replaced with dielectric sections 801A-801D as shown in FIG. 8B. Thus, the tunneling layer 208 can be separated into tunneling layer sections 218A-218D by the dielectric sections 801A-801D. In an example, the tunneling layer 208 has a SiO/SiON/SiO configuration, and thus SiON in the portions of the tunneling layer 208 can be oxidized into silicon oxide. Accordingly, the dielectric sections 801A-801D include silicon oxide while the tunneling layer sections 218A-218D include SiO/SiON/SiO. Subsequently, referring to FIG. 8C, the dielectric material can be deposited to fill the hole 610A in FIG. 8B, and thus form a dielectric section 910, as described above with reference to FIG. 7C. Thus, detailed descriptions are omitted for purposes of brevity.

Referring to FIGS. 8B and 9B, portions of the charge trapping layer 210 that are adjacent to the dielectric sections 801A-801D shown in FIG. 8B can further be replaced with dielectric sections 901A-901D. Thus, the charge trapping layer 210 can be separated into charge trapping layer sections 220A-220D by the dielectric sections 901A-901D. In an example, the charge trapping layer 210 has a SiN/SiON/SiN configuration, and thus SiON and SiN in the portions of the charge trapping layer 210 can be oxidized into silicon oxide. Accordingly, the dielectric sections 901A-901D include silicon oxide while the charge trapping layer sections 220A-220D include SiN/SiON/SiN. Subsequently, referring to FIG. 9C, the dielectric material can be deposited to fill the hole 610A in FIG. 9B, and thus form a dielectric section 910, as described above with reference to FIG. 7C. Thus, detailed descriptions are omitted for purposes of brevity.

The tunneling layer 208 and the charge trapping layer 210 are separated in FIGS. 9B and 9C. Alternatively, the tunneling layer 208 can remain in the closed-loop configuration and the charge trapping layer 210 can be separated into the charge trapping layer sections 220A-220D, for example, when the tunneling layer 208 includes only oxide material(s).

The descriptions of steps S1040 and S1050 for FIGS. 7B-7C can be suitably adapted to the oval profile shown in FIG. 14. Referring to FIGS. 14 and 15C, at S1040, the channel layer 306 in FIG. 14 can be divided into the channel layer sections 206A and 206C by replacing conductive material(s) (e.g., polysilicon) of the third portions of the channel layer 306 (e.g., adjacent to the axis C-C′) with a dielectric material or an oxidized material (e.g., silicon oxide) that is disposed between adjacent ones of the channel layer sections 206A and 206C. The oxidized material can form the dielectric sections 201A′ and 201C′. Thus, the third portions of the channel layer 306 can be replaced with the dielectric sections 201A′ and 201C′. The inner surface 248 then becomes the inner surfaces 244. In an example, an oxidation process, such as polysilicon oxidation, is used to oxidize the third portions of the channel layer 306 from polysilicon to silicon oxide. The dielectric material (e.g., silicon oxide) in the dielectric sections 201A′ and 201C′ can be identical to or different from the dielectric material(s) used in the dielectric structure 304. Subsequently, referring to FIG. 15D, at S1050, the dielectric material can be deposited to fill the hole 610 and thus form the dielectric section 910. The dielectric material(s) in the dielectric section 910, the dielectric sections 201A′ and 201C′, and the remaining portions of the dielectric structure 304 can be different or identical.

The descriptions of steps S1040 and S1050 for FIGS. 8B, 8C, 9B, and 9C can be suitably adapted to the oval profile shown in FIG. 15C. Referring to FIGS. 16C and 17C, the tunneling layer 208 and/or the charging trapping layer 210 can be further separated, for example, by oxidation process(es) after the channel layer 306 is separated, for example, by the oxidation process shown in FIG. 15C. After replacing the third portions of the channel layer 306 with the dielectric sections 201A′ and 201C′ as shown in FIG. 15C, portions of the tunneling layer 208 that are adjacent to the dielectric sections 201A′ and 201C′ can be replaced with dielectric sections 1501A and 1501C as shown in FIG. 16C. Thus, the tunneling layer 208 can be separated into tunneling layer sections 218A and 218C by the dielectric sections 1501A and 1501C. In an example, the tunneling layer 208 has a SiO/SiON/SiO configuration, and thus SiON in the portions of the tunneling layer 208 can be oxidized into silicon oxide. Accordingly, the dielectric sections 1501A and 1501C include silicon oxide while the tunneling layer sections 218A and 218C include SiO/SiON/SiO. Subsequently, referring to FIG. 16D, the dielectric material can be deposited to fill the hole 610 in FIG. 16C, and thus form a dielectric section 910, as described above with reference to FIG. 15D. Thus, detailed descriptions are omitted for purposes of brevity.

Referring to FIGS. 16C and 17C, portions of the charge trapping layer 210 that are adjacent to the dielectric sections 1501A and 1501C shown in FIG. 16C can further be replaced with dielectric sections 1701A and 1701C. Thus, the charge trapping layer 210 can be separated into charge trapping layer sections 220A and 220C by the dielectric sections 1701A and 1701C. In an example, the charge trapping layer 210 has a SiN/SiON/SiN configuration, and thus SiON and SiN in the portions of the charge trapping layer 210 can be oxidized into silicon oxide. Accordingly, the dielectric sections 1701A and 1701C include silicon oxide while the charge trapping layer sections 220A and 220C include SiN/SiON/SiN. Subsequently, referring to FIG. 17D, the dielectric material can be deposited to fill the hole 610 in FIG. 17C, and thus form a dielectric section 910, as described above with reference to FIG. 16D. Thus, detailed descriptions are omitted for purposes of brevity.

The tunneling layer 208 and the charge trapping layer 210 are separated in FIGS. 17C and 17D. Alternatively, the tunneling layer 208 can remain the closed-loop configuration and the charge trapping layer 210 can be separated into the charge trapping layer sections 220A and 220C, for example, when the tunneling layer 208 include only oxide material(s).

The process 1000 and the 3D semiconductor device 100 that includes the channel structure 18 (e.g., the channel structure 18(1)-(3)) can offer advantages over a related semiconductor device and a related process used to manufacture the related semiconductor device. The related semiconductor device can include a channel structure having a gate dielectric structure and a closed-loop channel layer formed through a channel hole with multiple layers of materials concentrically arranged, for example, circularly around a central axis that is parallel to the vertical direction. The channel hole can be circular.

When a cross-section (perpendicular to the vertical direction) of the channel hole in the related semiconductor device has an identical size as that of the channel hole in the 3D semiconductor device 100, the bit density of the 3D semiconductor device 100 can be N (e.g., N=4) times that of the related semiconductor device as the open-loop channel layer is separated into the N (e.g., 4) channel layer sections (e.g., 206A-206D). N is an integer larger than 1.

When a number of gate line layers in the related semiconductor device is identical to that of the gate line layers 12 in the 3D semiconductor device 100 and the bit density of the related semiconductor device is identical to that of the 3D semiconductor device 100 by reducing a size of the channel hole in the related semiconductor device, an etching window used to etch the channel hole 341 for the 3D semiconductor device 100 can be significantly larger than that of the related semiconductor device. Thus, better etching uniformity can be achieved and tilting issues in channel hole etching can be alleviated for the 3D semiconductor device 100.

In an example, the channel hole in the related semiconductor device can be formed by combining sub-channel holes in multiple stacks (e.g., an upper stack and a lower stack) to increase the bit density without sacrificing etching uniformity. However, alignment issues of the sub-channel holes in the multiple stacks can be challenging. For example, misalignment can occur. A connection issue of channel holes based on a double pattern may become worse, and thus manufacturing the related semiconductor device with a higher bit density can become challenging. Using the 3D semiconductor device 100 can achieve the same bit density and avoid the alignment issues and/or the connection issue associated with the double pattern.

In an example, a first size of an etching window used to etch the channel hole for the related semiconductor device is similar to a second size of an etching window used to etch the hole 510 in FIG. 5 for the 3D semiconductor device 100 (or the pre-channel structure 400). The etching process used to etch the hole 510 can achieve better uniformity than that used to etch the channel hole for the related semiconductor device for the following reasons. The etching process used to etch the hole 510 etches the dielectric material(s) in the dielectric structure 304. The dielectric material(s) can be uniformly distributed along the vertical direction. In an example, the dielectric material(s) includes one material, such as silicon oxide, that is uniformly distributed along the vertical direction. On the other hand, the etching process used to etch the channel hole for the related semiconductor device etches multiple layers having multiple materials, such as alternating layers of silicon oxide and silicon nitride. Thus, etching the uniformly distributed dielectric material(s) in the 3D semiconductor device 100 can achieve better etching uniformity than etching the non-uniformly distributed alternating layers of silicon oxide and silicon nitride in the related semiconductor device.

According to aspects of the disclosure, the bit density of the 3D semiconductor device 100 can be improved based on a split channel configuration (or a split cell configuration including split cells or MCs). The split MCs can be formed by splitting a single closed-loop channel layer into multiple separate channel layer sections in an open-loop channel layer. Thus, a single MC string can be split into multiple MC strings. Accordingly, the issues (e.g., etching uniformity, tilting issue, the alignment issue, the connection issue, or the like) experienced in the related semiconductor device can be avoided.

Steps in the process 1000 can be suitably adapted, and thus can be modified, omitted, and combined. For example, at S1010, the channel hole 341 can be formed in the stack that includes the plurality of gate line layers 12 and the plurality of insulating layers 14. Alternatively, at S1010, the stack includes alternating sacrificial gate line layers and the insulating layers 14. A step can be added, for example, after implementing S1050 where the sacrificial gate line layers can be replaced with the gate structures 312 and the corresponding gate line layers 12 to form the strings of transistors based on the channel layer sections 206A-206D and the gate structures 312. Further, top channel contacts (e.g., the top channel contacts 214A-D in FIGS. 2A, 2C, 2D, 2E, 7C, 8C, and 9C, the top channel contacts 214A and 214C in FIGS. 2F, 2G, 2H, 15B, 15D, 16B, 16D, 17B, and 17D) can be formed.

Any suitable order can be used to implement the steps in the process 1000. The process 1000 can be combined with other process flows to manufacture other suitable semiconductor components (not shown), such as other types of transistors, bipolar junction transistors, resistors, capacitors, inductors, diodes, fuses, and the like on the 3D semiconductor device 100. In various embodiments, the process 1000 can also be combined with additional process flows to manufacture other suitable circuits, for example, a peripheral circuit for driving the MCs, a sense amplifier for reading data stored in the MCs, a decoding circuit, and the like. The steps of the process 1000, including any descriptions given with reference to FIGS. 2A-2D and 3-10, are merely exemplary and are not intended to be limiting.

It should be noted that additional steps can be provided before, during, and after the process 1000, and one or more of the steps described can be replaced, eliminated, or performed in different order for additional embodiments of the process 1000. For example, the gate line contacts 22 in the staircase regions, and the gate line split structures 20a-20b in the array region can be formed after the channel structures 18 are formed. Moreover, various additional interconnect structures (e.g., metallization layers having conductive lines and/or vias) may be formed over the 3D semiconductor device 100. Such interconnect structures can electrically connect the 3D semiconductor device 100 with other contact structures and/or active devices to form functional circuits. Additional device features such as passivation layers, input/output structures, and the like may also be formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purpose and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a channel hole through a stack over a substrate of the semiconductor device, a sidewall of the channel hole extending along a vertical direction perpendicular to the substrate;
forming a gate dielectric structure, a channel layer, and a dielectric structure that extend along the vertical direction and in the channel hole, the gate dielectric structure being formed along the sidewall of the channel hole, the dielectric structure being formed over the channel layer; and
separating the channel layer into channel layer sections to form a channel structure that includes the gate dielectric structure and the channel layer sections for respective strings of transistors.

2. The method of claim 1, wherein the separating the channel layer into channel layer sections comprises:
forming a hole inside the dielectric structure using a first etching process with an etching mask; and
removing portions of the dielectric structure adjacent to first portions of the channel layer using a second etching process, second portions of the channel layer being separated from the hole by the dielectric structure.

3. The method of claim 2, wherein:
forming the gate dielectric structure includes forming a barrier layer, a charge trapping layer, and a tunneling layer sequentially along the vertical direction, the barrier layer being formed along the sidewall of the channel hole and in contact with the stack;
forming the channel layer includes forming the channel layer over an inner surface of the tunneling layer;
forming the dielectric structure includes forming the dielectric structure over an inner surface of the channel layer;
the stack includes alternating sacrificial layers and insulating layers; and
the method further includes replacing the sacrificial layers with gate line layers.

4. The method of claim 3, wherein the separating the channel layer further comprises:
removing the first portions of the channel layer by an etching process to separate the channel layer into the channel layer sections, the hole including voids corresponding to the removed first portions of the channel layer; and
depositing a dielectric material, the dielectric material deposited in the voids being disposed between adjacent ones of the channel layer sections.

5. The method of claim 4, wherein the removing the first portions of the channel layer further comprises removing first portions of the tunneling layer that are adjacent to the first portions of the channel layer by the etching process to separate the tunneling layer into tunneling layer sections, the dielectric material being deposited between adjacent ones of the tunneling layer sections.

6. The method of claim 4, wherein the removing the first portions of the channel layer further comprises:
removing first portions of the tunneling layer that are adjacent to the first portions of the channel layer by the etching process to separate the tunneling layer into tunneling layer sections; and
removing first portions of the charge trapping layer that are adjacent to the first portions of the tunneling layer by the etching process to separate the charge trapping layer into charge trapping layer sections, the dielectric material being deposited between adjacent ones of the tunneling layer sections and adjacent ones of the charge trapping layer sections.

7. The method of claim 2, wherein the separating the channel layer further comprises:
oxidizing the first portions of the channel layer into an oxidized material to separate the channel layer into the channel layer sections, the oxidized material being disposed between adjacent ones of the channel layer sections; and
depositing a dielectric material into the hole.

8. The method of claim 7, wherein
the gate dielectric structure includes a barrier layer, a charge trapping layer, and a tunneling layer that are sequentially formed along the vertical direction, the barrier layer being formed along the sidewall of the channel hole; and
the method further includes oxidizing portions of the tunneling layer to separate the tunneling layer into tunneling layer sections and/or oxidizing portions of the charge trapping layer to separate the charge trapping layer into charge trapping layer sections, the tunneling layer sections and the charge trapping layer sections corresponding to the channel layer sections.

9. The method of claim 1, wherein
a cross-section of the channel hole that is perpendicular to the vertical direction has a plurality of axes of symmetry; and
a first distance is a smallest distance among distances between a center point at which the plurality of axes of symmetry intersects and respective points on the sidewall of the cross-section of the channel hole;
a second distance is a largest distance among the distances; and
the first distance is less than the second distance.

10. The method of claim 9, wherein the cross-section of the channel hole has one of an oval profile, a trefoil profile, a quatrefoil profile, and a star profile.

11. The method of claim 9, wherein a number of the plurality of axes of symmetry is larger than 1.

12. The method of claim 9, wherein a ratio of the second distance over the first distance is in a range of 1.5 to 2.

13. The method of claim 1, wherein
the channel layer sections include four channel layer sections, each of the four channel layer sections corresponding to a different one of the strings of transistors; and
the four channel layer sections are arranged at ends of perpendicular axes of symmetry in a cross-section of the channel hole that is perpendicular to the vertical direction.

14. A semiconductor device, comprising:
a channel hole in a stack over a substrate of the semiconductor device, a sidewall of the channel hole extending along a vertical direction that is perpendicular to the substrate;
a channel structure that is disposed in the channel hole, the channel structure extending along the vertical direction, wherein a cross-section of the channel structure that is perpendicular to the vertical direction includes physically separated channel layer sections for respective strings of transistors and a first dielectric material disposed between adjacent ones of the channel layer sections; and
gate structures in the stack that surround the channel structure.

15. The semiconductor device of claim 14, wherein the channel structure further comprises a gate dielectric structure, the gate dielectric structure including:
a barrier layer that is formed along the sidewall of the channel hole and extends in the vertical direction, the barrier layer being in contact with the gate structures;
a charge trapping layer that is formed over an inner surface of the barrier layer; and
a tunneling layer that is formed over an inner surface of the charge trapping layer, the channel layer sections being arranged over an inner surface of the tunneling layer and the first dielectric material being in contact with the tunneling layer.

16. The semiconductor device of claim 15, wherein the channel structure further includes a second dielectric material that is formed over inner surfaces of the respective channel layer sections, the second dielectric material being different from the first dielectric material.

17. The semiconductor device of claim 15, wherein cross-sections of the barrier layer, the charge trapping layer, and the tunneling layer perpendicular to the vertical direction have a closed-loop configuration.

18. The semiconductor device of claim 15, wherein:
a cross-section of the tunneling layer that is perpendicular to the vertical direction is discontinues;
the tunneling layer includes a plurality of tunneling layer sections that correspond to the respective channel layer sections; and
the plurality of tunneling layer sections is spaced apart from each other by the first dielectric material.

19. The semiconductor device of claim 18, wherein:
a cross-section of the charge trapping layer that is perpendicular to the vertical direction is discontinuous;
the charge trapping layer includes a plurality of charge trapping layer sections that correspond to the respective tunneling layer sections; and
the plurality of charge trapping layer sections is spaced apart from each other by the first dielectric material.

20. The semiconductor device of claim 14, wherein
a cross-section of the channel hole that is perpendicular to the vertical direction has a plurality of axes of symmetry;
a first distance is a smallest distance among distances between a center point at which the plurality of axes of symmetry intersects and respective points on the sidewall of the cross-section of the channel hole;
a second distance is a largest distance among the distances; and
the first distance is less than the second distance.
